(19) United States
(12) Patent Application Publication
(10) Pub. No.: US 2014/0077161 A1
(43) Pub. Date: Mar. 20, 2014

(54) HIGH PERFORMANCE GRAPHENE TRANSISTORS AND FABRICATION PROCESSES THEREOF

(71) Applicants: Xiangfeng Duan, Los Angeles, CA (US); Yu Huang, Los Angeles, CA (US); Lei Liao, Wuhan (CN); Jingwei Bai, Los Angeles, CA (US)

(72) Inventors: Xiangfeng Duan, Los Angeles, CA (US); Yu Huang, Los Angeles, CA (US); Lei Liao, Wuhan (CN); Jingwei Bai, Los Angeles, CA (US)

(73) Assignee: THE REGENTS OF THE UNIVERSITY OF CALIFORNIA

(21) Appl. No.: 14/002,663

(22) PCT Filed: Mar. 2, 2012
(86) PCT No.: PCT/US12/27606

§ 371 Date: Oct. 25, 2013

Related U.S. Application Data
(60) Provisional application No. 61/448,562, filed on Mar. 2, 2011.
(60) Provisional application No. 61/494,374, filed on Jun. 7, 2011.

(51) Int. Cl. H01L 29/40; H01L 29/16; H01L 29/06; H01L 29/775

(52) U.S. Cl. CPC H01L 29/408; H01L 29/775; H01L 29/1606; H01L 29/0673; B82Y 10/00
USPC 257/29; 977/938

(57) ABSTRACT

A graphene transistor includes: (1) a substrate; (2) a source electrode disposed on the substrate; (3) a drain electrode disposed on the substrate; (4) a graphene channel disposed on the substrate and extending between the source electrode and the drain electrode; and (5) a top gate disposed on the graphene channel and including a nanostructure.

### CROSS-REFERENCE TO RELATED APPLICATIONS

This application claims the benefit of U.S. Provisional Application Ser. No. 61/448,562, filed on Mar. 2, 2011, and the benefit of U.S. Provisional Application Ser. No. 61/494,374, filed on Jun. 7, 2011, the disclosures of which are incorporated herein by reference in their entireties.

### STATEMENT REGARDING FEDERALLY SPONSORED RESEARCH OR DEVELOPMENT

This invention was made with Government support under Grant No. OD004342, awarded by the National Institutes of Health, and Grant No. 0956171, awarded by the National Science Foundation. The Government has certain rights in this invention.

### FIELD OF THE INVENTION

The invention generally relates to transistors and, more particularly, high performance graphene transistors and fabrication processes of such transistors.

### BACKGROUND

Graphene has attracted considerable interest as an electronic material due to its exceptionally high carrier mobility and tunable bandgap. Various strategies have been explored to fabricate field-effect transistors (FETs) based on graphene. Many of these efforts employ a silicon substrate as a global back gate and silicon oxide as a gate dielectric. Although back-gated devices have led to interesting scientific discoveries, such devices can have limited use for practical applications due to a high gate switching voltage and an inability to independently address individual devices on the same chip. Top-gated devices with high quality dielectrics can significantly reduce the switching voltage and readily allow independently addressable device arrays and functional circuits.

The gate dielectric is an important component of a transistor, which can impact various device parameters including transconductance. In order to develop top-gated graphene transistors, it is desirable to effectively integrate high quality gate dielectrics, such as high-k dielectrics. However, it has been rather challenging to deposit dielectrics onto graphene without introducing defects. The deposition of high-k dielectrics is typically achieved using atomic layer deposition (ALD), which involves reactive surface groups. Unfortunately, functionalization of a graphene surface for ALD can either introduce undesired impurities or can break chemical bonds in the graphene lattice, leading to a significant degradation in carrier mobilities. Physical vapor deposition (PVD), such as electron-beam (or e-beam) evaporation or sputtering, has been used to deposit dielectrics without the need of surface functionalization. However, the PVD process has yielded lower quality dielectrics and can also cause significant damages to graphene. As a result, the mobility values observed in the top-gated devices are typically nearly one order of magnitude smaller than what can be achieved in back-gated devices. To realize high performance, graphene-based electronics, it is desirable to develop alternative approaches to integrate high quality dielectrics without damaging the pristine graphene.

It is against this background that a need arose to develop the graphene transistors and related systems and processes described herein.

### SUMMARY

One aspect of the invention relates to graphene transistors. In one embodiment, a graphene transistor includes: (1) a substrate; (2) a source electrode disposed on the substrate; (3) a drain electrode disposed on the substrate; (4) a graphene channel disposed on the substrate and extending between the source electrode and the drain electrode; and (5) a top gate disposed on the graphene channel and including a nanostructure.

In another embodiment, a graphene transistor includes: (1) a source electrode; (2) a drain electrode; (3) a graphene channel extending between the source electrode and the drain electrode; and (4) a gate stack including: (a) a dielectric layer disposed on the graphene channel; (b) an electrically conductive layer disposed on the dielectric layer; and (c) a dielectric spacer at least partially covering sidewalls of the electrically conductive layer.

Another aspect of the invention relates to fabrication processes of graphene transistors. A further aspect of the invention relates to circuits including graphene transistors.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings.

FIG. 1: Schematic illustration of the fabrication process to obtain top-gated graphene transistors using dielectric oxide nanowires as the etching mask and top gate dielectric. (a) A dielectric nanowire is aligned on top of graphene, using a dry-transfer process without any additional chemical functionalization to reduce the introduction defects or impurities into the graphene/dielectric interface, and the source-drain electrodes are fabricated by e-beam lithography. (b) Oxygen-plasma etching is used to remove the unprotected graphene, thereby selecting leaving a graphene strip underneath the dielectric nanowires connected to two larger graphene blocks underneath the source and drain electrodes. (c) The top gate electrode is defined through lithography and metallization process.

FIG. 2: Schematic illustration of the fabrication process to obtain top-gated graphene transistors using dielectric oxide nanoribbons as the etching mask and top gate dielectric. (A) A dielectric nanoribbon is aligned on top of graphene using a dry-transfer process without any additional chemical functionalization to reduce the introduction of defects or impurities into the graphene-dielectric interface, and the source-drain electrodes are fabricated by e-beam lithography. (B) Oxygen plasma etch is used to remove the unprotected graphene, thereby selectively leaving a graphene strip underneath the dielectric nanoribbon connected to two larger graphene blocks underneath the source and drain electrodes. (C) The top gate electrode is defined through lithography and metallization process.

FIG. 3: Schematic illustration of the fabrication process to obtain top-gated graphene transistors using Si/HfO₂ core/shell nanowires as the etching mask and top gate. (a) and (e) An Si/HfO₂ core/shell nanowire is aligned on top of graphene using a dry-transfer process, and the source-drain electrodes are fabricated by e-beam lithography. (b) and (f) Oxygen plasma etch is used to remove the unprotected graphene, thereby selectively leaving a graphene strip underneath the nanowire connected to two larger graphene blocks underneath the source and drain electrodes. (c) and (g) The top-half of the HfO₂ shell was etched away using argon plasma to expose the silicon core for contact to an external electrode. (d) and (h) The top gate electrode is defined through lithography and metallization process.

FIG. 4: Schematic illustration of the fabrication process to obtain a top-gated graphene transistor using a GaN nanowire as the self-aligned top-gate. (a) A GaN nanowire is aligned on top of graphene using a dry-transfer process without any additional chemical functionalization to reduce the introduction of defects or impurities into the interface. (b) The external source, drain, and top gate electrodes are fabricated by e-beam lithography. (c) Deposition of a 10 nm Pt metal film to form the source and drain electrodes self-aligned with the nanowire gate. (d) The schematic illustration of the cross-section of the device. (e) The SEM cross-section image of GaN nanowire after Pt self-aligned deposition, illustrating well separated source-drain electrode due to nanowire shadow effect. (f) Schematic energy band diagrams of a single GaN nanowire on graphene. E_{F}, E_{C}, and E_{V} are Fermi level, conduction band, and valence band, respectively.

FIG. 5: Schematic illustration of a high-speed graphene transistor with a Co₂Si/Al₂O₃ core/shell nanowire as the self-aligned top gate. (a) Schematic illustration of the three-dimensional view of the device layout. (b) Schematic illustration of the cross-sectional view of the device. In this device, the Co₂Si/Al₂O₃ core/shell nanowire defines the channel length, with the Al₂O₃ shell in functioning as the gate dielectrics, and the metallic Co₂Si core functioning as the self-integrated local gate.

FIG. 6: Schematic illustration of the scalable fabrication of the top-gated graphene transistors with self-aligned nanowire gates. (a) Chemical vapor deposition grown graphene is transferred onto a glass substrate. (b) The graphene is patterned by photolithography. (c) The electric-field electrodes are patterned using photolithography. (d) The nanowires are assembled by dielectrophoresis. (e) The external source, drain, and top gate electrodes are fabricated using e-beam lithography. (f) Deposition of 10-nm Pt metal film to form the source and drain electrodes that are self-aligned with the nanowire gate.

FIG. 7: Schematic illustration of the fabrication of self-aligned graphene transistors with transferred gate stacks. (A) A 50-nm gold film is first deposited on a Si/SiO₂ substrate by e-beam evaporation followed by ALD of Al₂O₃ film. (B) Reactive ion etch (RIE) process is employed to pattern the dielectric strips after lithography and metallization process. (C) The gate sidewall spacer is formed by depositing a thin layer Al₂O₃ film using ALD approach. (D) An anisotropic RIE process is used to etch away unwanted Al₂O₃ film on the top surface of the gate metal and the substrate. (E) A layer of polymer (which has a glass transition temperature close to the thermal tape releasing temperature) is spin-casted before applying thermal releasing tape and peeling off the gate stack. (F) The patterned top gate stacks are peeled off from the Si wafer. After etching away the gold film, the gate stacks can be readily transferred onto a desired graphene substrate through a thermal releasing process. (G) Polymer is removed by an acetone rinse, selectively leaving the gate stacks on top of graphene strips. (H) The external source, drain, and top gate electrodes are fabricated using e-beam lithography. Deposition of 5 nm/10 nm Pd/Au metal film to form the self-aligned source and drain electrodes. (I) The cross-sectional view of the self-aligned device.

FIG. 8: Characterization of ZrO₂ nanowires and top-gated graphene transistors with ZrO₂ nanowires as the gate dielectric. a) An SEM image of ZrO₂ nanowires. b) A TEM image of a ZrO₂ nanowire; the inset shows the SAED pattern of a ZrO₂ nanowire. c) The EDX spectrum of ZrO₂ nanowires shows zirconium and oxygen signals. The carbon signal comes from the carbon membrane on TEM grid. d) The SEM image of a top-gated graphene transistor with ZrO₂ nanowire as top gate dielectric. The gate length is about 500 nm, and the diameter of the nanowire is about 50 nm. The inset shows an AFM image of a ˜15 nm wide graphene strip obtained under ZrO₂ nanowire after oxygen-plasma etching. The scale bar indicates 200 nm. e) Gate-leak current versus top gate voltage. The leak current is negligible within a voltage range of ±2 V. f) I_{ds}−V_{ds} output characteristics at variable top gate voltage starting from 0.4 V at the bottom to −1.0 V at the top in the step of −0.2 V. g) The transfer characteristics I_{ds}−V_{TG} at various V_{ds}=0.01, 0.10, and 1.0 V. h) I_{ds}−V_{TG} (solid curve) and I_{ds}−V_{BG} (dash curve) transfer characteristics at V_{ds}=1 V. i) Transconductance, gₘ, as a function of V_{TG} and V_{BG} (inset).

FIG. 9: Independently addressable graphene device array. a) An SEM image of two independently addressable top-gated graphene FETs. b) Transfer characteristics of two top-gated graphene FETs at V_{ds}=0.1 V. c) The SEM image of a logic OR gate built from graphene transistors. The inset shows the schematic circuit diagram. d) The OR gate output characteristics with double top-gates. The operating voltage is V_{dd}=1 V. The inputs for the two gates, A and B, are 1 V for state 1 and 0 for state 0.

FIG. 10: Evaluation of the Al₂O₃ nanoribbons as dielectric material. (A) TEM image (inset, SAED pattern) and (B) HRTEM image of an Al₂O₃ nanoribbon show substantially perfect crystalline α-Al₂O₃ structure. (C) AFM image of an Al₂O₃ nanoribbon with thickness ˜50 nm. The image area is 5 μm×5 μm. (D) AFM image of the surface of the Al₂O₃ nanoribbon, highlighting the smooth surface with a root mean square roughness <0.2 nm. The image area is 250 nm×250 nm. (E) The schematic device diagram (inset) and SEM image of an Al₂O₃ nanoribbon metal-insulator-metal (MIM) device. (F) Current density-electric field (J-E) curve of an MIM device made from an Al₂O₃ nanoribbon, and the inset shows the corresponding Fowler-Nordheim (F-N) curve.

FIG. 11: Characterization of the graphene/Al₂O₃ nanoribbon interface. (A) Raman spectra of the graphene with (b) and without (a) Al₂O₃ nanoribbon covering. The inset shows the optical image of an Al₂O₃ nanoribbon on graphene, and the scale bar is 2 nm. There is no D-band in either spectrum, indicating that Al₂O₃ nanoribbon does not introduce any appreciable defects into graphene lattice. (B) A cross-section TEM image of the top gate stack, and the scale bar is 100 nm. The inset shows a SEM image of a typical device, and the scale bar indicates 5 nm. The dotted line in the inset shows the cross-section cutting direction. (C) A cross-section HRTEM image of the interface between Al₂O₃ nanoribbon and a tri-layer graphene. The partially incomplete graphene layers in the image are caused by electron beam damage during the TEM imaging process.

FIG. 12: Room temperature electrical properties of the top-gated graphene device using Al₂O₃ nanoribbon as the gate dielectric. (A) I_{ds}−V_{ds} output characteristics, with the channel width and length of the device being 2.1 μm and 4.1 μm (B) Transfer characteristics at V_{ds}=1 V for the device using top and back gate (inset). (C) Transconductance g, as a function of top gate voltage V_{TG}, and the inset shows gₘ vs. V_{BG}. The plots indicate the top-gated gₘ is about 15 times larger than the back-gated gₘ. (D) Two-dimensional plot of the device conductance at varying V_{BG} and V_{TG} bias. The unit in the shading scale is μS. (E) The top gate Dirac point V_{TG}_{_{—}}_{Dirac} at different V_{BG}. (F) Experimental plot and modeling fitting of Rₜₒₜ vs. V_{TG}−V_{TG}_{_{—}}_{Dirac} relation to derive the contact resistance and carrier mobility.

FIG. 13: TEM characterization of Si/HfO₂ core/shell nanowires. (a) Schematic illustration of the synthesis of Si/HfO₂ core/shell nanowires. Highly doped p-type silicon nanowire arrays were synthesized using catalytic chemical vapor deposition. ALD was used to grow HfO₂ shell with controlled thickness. (b) TEM and (c) HRTEM images of Si/HfO₂ core/shell nanowires.

FIG. 14: Characterization of the graphene/HfO₂ interface. (a) A SEM image of a typical device. (b) A cross-section TEM image of the top gate stack. (c) A cross-section HRTEM image of the interface between nanowires and multi-layered graphene, which indicates that the graphene layers are intimately integrated with the Si/HfO₂ nanowire without any noticeable gap or impurities between them.

FIG. 15: Room temperature electrical properties of the top-gated graphene device using Si/HfO₂ core/shell nanowire as the top gate. (a) Gate leakage current versus top gate voltage. The leakage current is negligible within ±1 V range. (b) I_{ds}−V_{ds} output characteristics at variable top gate voltage starting from 0.6 V at bottom to −1.0 V at top in the step of −0.2 V. (c) The transfer characteristics I_{ds}−V_{TG} at V_{ds}=0.10 V and 1.0 V. (d) I_{ds}−V_{TG} and I_{ds}−V_{BG} transfer characteristics at V_{ds}=1 V. (e) Transconductance as a function of top gate voltage V_{TG} and back gate voltage V_{BG} (inset). (f) Two-dimensional plot of the device conductance at varying V_{BG} and V_{TG} bias, and the unit in the shading scale is μS.

FIG. 16: The electrical properties of GaN nanowire/graphene diode and transistor. (a) An SEM image of GaN nanowire/graphene device. (b) I−V characteristics of the GaN nanowire and graphene, respectively. (c) Typical Schottky-diode-like I−V characteristic curve for GaN/graphene device. (d) I_{ds}−V_{TG} transfer characteristics at V_{ds}=0.1 V for a graphene transistor with the GaN nanowire as the local top gate.

FIG. 17: Room temperature electrical properties of the self-aligned graphene transistor. (a) An SEM image of a self-aligned graphene device with GaN nanowire gate. The scale bar is 2 μm, and the width the nanowire side is 100 nm. (b) Transfer characteristics at V_{ds}=1 V for the device using the nanowire top gate. The inset shows the transfer characteristics at V_{ds}=0.1 V. The channel width is 2.0 μm. (c) I_{ds}−V_{ds} output characteristics at variable top-gate voltages. (d) Transconductance gₘ as a function of top gate voltage V_{TG} at V_{ds}=1 V. The inset shows gₘ vs. V_{TG} at V_{ds}=0.1 V. (e) The conductance vs. V_{TG} bias at varying V_{BG}. (f) The top gate Dirac point V_{TC}_{_{—}}_{Dirac} at different V_{BG}.

FIG. 18: Channel length scaling of RC delay time, transit time, and cut-off frequency. (a) RC delay time τ_{RC} and transit time τₜ at V_{ds}=1 V vs. channel length for several self-aligned graphene devices of variable channel lengths (b) The calculated cut-off frequency f_{T} at V_{ds}=1 V vs. channel length for several self-aligned graphene devices of variable channel lengths.

FIG. 19: Characterization of Co₂Si and Co₂Si/Al₂O₃ core/shell nanowires. (a) SEM image of the Co₂Si nanowires. The nanowires were synthesized through a chemical vapor deposition process with the diameters typically in the range of about 100 nm-300 nm and the lengths of about 10 μm. (b) TEM image of a Co₂Si/Al₂O₃ core/shell nanowire shows an uniform coating of the amorphous Al₂O₃ (light contrast) surrounding the single-crystal Co₂Si core (dark contrast). (c) The I−V characteristic of a single Co₂Si nanowire in two- and four-terminal measurements to determine the nanowire resistance and resistivity. The inset shows a SEM image of the device, and the scale bar is 3 μm.

FIG. 20: Room temperature electrical characteristics of the graphene transistors with a self-aligned nanowire gate. (a) SEM images of a graphene transistor with a self-aligned nanowire gate. The inset shows an optical microscope image of the overall device layout. (b) The cross-sectional SEM image of a typical device shows the self-aligned Pt thin film source and drain electrodes are well separated by the nanowire gate and precisely positioned next to the nanowire gate. The graphene below the nanowire gate is not clearly visible. (c) and (d) I_{ds}−V_{TG} transfer characteristics at V_{ds}=1 V before and after the deposition of the self-aligned Pt source-drain electrodes. (e) The I_{ds}−V_{ds} output characteristics at various gate voltages (V_{TG}=0.0, 0.4, 0.8, 1.2, 1.6, and 2.0 V) and V_{ds}=1 V for the self-aligned device. (f) Transconductance gₘ as a function of top gate voltage V_{TG} before and after the deposition of the self-aligned Pt source-drain electrodes, highlighting the self-alignment process increases the peak transconductance by a factor of >60. (g) Two dimensional plot of the conductance for varying V_{BG} and V_{TG} bias for self-aligned device. The unit in the shading scale is mS. (h) The top gate Dirac point V_{TG}_{_{—}}_{Dirac} at different V_{BG}, with which one can derive C_{TG}/C_{BG}=38.

FIG. 21: Measured small-signal current gain |h21| and power gain |U| as a function of frequency f at V_{ds}=1 V and V_{TG}=1 V. (a) For a device with gate length=144 nm; and (b) For a device with gate length=210 nm. The insets show the f_{T} extraction by Gummel's method.

FIG. 22: The top-gated graphene transistors. (a) The dark-field optical image of dielectrophoretic assembled nanowire array, and the scale bar is 50 μm. Each pair of electrodes is bridged by a single nanowire. (b) The optical image of a self-aligned graphene transistor array, and the scale bar is 100 μm. (c) The optical image of an individual self-aligned graphene transistor, and the scale bar is 50 μm. (d) The SEM image of a graphene transistor with a self-aligned nanowire gate.

FIG. 23: Room temperature DC and RF characteristics of the self-aligned graphene transistor with 170 nm gate. (a) I_{ds}−V_{ds} output characteristics of the device at various gate voltages. (b) I_{ds}−V_{TG} transfer characteristics at V_{ds}=−1 V. (c) Transconductance gₘ at V_{ds}=−1 V as a function of top gate voltage V_{TG}. (d) As-measured S parameters for the graphene RF transistor. (e) The small-signal current gain |h21| as a function of frequency f at V_{ds}=−1 V, highlighting an intrinsic cut-off frequency of about 72 GHz, and a high extrinsic cut-off frequency exceeding about 50 GHz without de-embedding process. (f) The equivalent circuit topology.

FIG. 24: Graphene transistor based RF doubler. (a) The circuit diagram of an RF doubler. (b) The I_{ds}−V_{TG} of an ambipolar graphene transistor shows substantially symmetrical behavior around the Dirac point. (c) Measured input (red) and output (black) signals of the frequency-doubling circuit when the graphene device is gated near the Dirac point, with the input frequency at about 1.05 GHz, and the output frequency at about 2.10 GHz. (d) Output spectrum with single RF input f_{RF}=1.05 GHz. The frequency doubling is visible. The signal power at 2f_{RF}=2.1 GHz is about 10 db higher than the signal power at f_{RF}=1.05 GHz without filtering.

FIG. 25: Graphene transistor based RF mixer. (a) The circuit diagram of a graphene transistor based RF mixer. (b) Measured DC transconductance gₘ (line) and f_{T} (triangle) as a function of gate voltage. (c) Output spectrum with LO input W₁=2.98 GHz and RF input W₂=6.72 GHz at equal power at V_{ds}=−1 V, and V_{TG}=0.3 V. The presence of strong signal power at W₂−W₁ and W₁+W₂ demonstrates mixing operations up to about 10 GHz. (d) Output spectrum with LO input W₁=2.98 GHz and RF input W₂=6.72 GHz at equal power at V_{ds}=−0.2 V, and V_{TG}=0.3 V, in which W₁+W₂ at 9.70 GHz disappears, demonstrating the RF mixer frequency limit depends on the gₘ and the extrinsic f_{T} of the device. (e) Output power of the fundamental and third-order intermodulation (W₂−2W₁) as a function of the input power to extract the IIP3 and OIP3. (f) Output spectrum with LO input W₁=1.26 GHz and RF input W₂=2.01 GHz at equal power (7 dbm) at V_{ds}=−1 V, and V_{TG}=0.3 V. There is no third-order intermodulation frequency, which demonstrates that odd-order intermodulation can be significantly suppressed in graphene transistor mixers operating near the Dirac point due to the symmetrical transfer characteristics.

FIG. 26: (a) The Raman spectrum of CVD graphene, and the inset shows a photograph of a piece of CVD graphene on glass. (b) The transfer characteristics of a typical back-gated CVD graphene transistor on silicon/silicon oxide, with which the carrier mobility of graphene was derived (about 1000-2000 cm²/V·s).

FIG. 27: The self-aligned graphene transistor. (A) Photo image of large scale self-aligned devices with transferred gate stacks on glass substrate. (B) Optical image of self-aligned graphene transistors on 300 nm SiO₂/Si substrate. The scale bar is 100 μm. (C) The SEM image of a graphene transistor with transferred gate stack. The scale bar is 2 μm. (D) Cross-sectional TEM image of the overall device layout. The scale bar is 30 nm.

FIG. 28: Room-temperature DC electrical characteristics of the CVD graphene transistors with transferred gate stacks. (A) The distribution of device mobility before and after the dielectric transfer process. (B) I_{ds}−V_{ds} output characteristics at various gate voltages (V_{TG}=0, 1, 1.5, 2.0 and 2.5 V) for a 300 nm channel length self-aligned device. (C) The transfer characteristics at different bias voltage for the 300 nm channel length self-aligned device (V_{ds}=−0.1, −0.2, −0.4 and −0.6 V). (D) Two-dimensional plot of the device conductance for varying V_{BG} and V_{TG} biases for the self-aligned graphene device. (E) Transfer characteristics of self-aligned graphene transistors at V_{ds}=−0.6 V with channel lengths of 3 μm, 1 μm, 300 nm, and 100 nm. The channel width is 5 μm for all devices. (F) The corresponding transconductance of the devices shown in FIG. 3E at V_{ds}=−0.6 V.

FIG. 29: Radio frequency performance of self-aligned CVD graphene transistors. (A-C) Small-signal current gain |h21| vs. frequency for three devices with a channel length of (A) 220 nm, (B) 100 nm, and (C) 46 nm at room temperature. The cut-off frequencies are 57 GHz, 110 GHz, and 212 GHz, respectively, at a dc bias of 0.6 V. Insets involve linear fitting using Gummel's method, showing extraction of cut-off frequencies substantially identical to the value obtained in the main panel for each device. (D) Peak f_{T} as a function of gate length from over 40 devices with 3 different dielectric thickness.

FIG. 30: Room-temperature DC and RF characteristics of the self-aligned, peeled graphene transistor with transferred gate stacks. (A) The transfer characteristics and corresponding transconductance at a DC bias voltage of 1 V for the 67 nm channel length self-aligned, peeled graphene device. (B) Small-signal current gain |h21| vs. frequency for the 67 nm peeled graphene device under two different DC bias voltage. The cut-off frequency is about 427 GHz for 1.1 V bias (solid block) and 169 GHz for 0.4 V bias (hollow block). The inset shows the extraction of f_{T} by Gummel's method.

FIG. 31: The Raman spectrum of CVD grown graphene on SiO₂/Si substrate. The ratio of G peak to 2D peak reveals the single layer property of CVD grown graphene.

FIG. 32: Gate-leakage current vs. top gate voltage (I_{gs}−V_{TG}). With the self-aligned Pd/Au source drain electrodes, the gate-source leakage remains very small compared to the channel current in the range of V_{TG}=−4 V to 4 V. The leakage current does not significantly affect the transistor characteristics.

FIG. 33: The back and forth sweep of I_{ds}−V_{TG} curve of a peeled graphene device with transferred gate stack. The curve shows a small hysteresis <0.07 V under ambient conditions at V_{ds}=−1 V, highlighting the excellent dielectric quality of the gate stack.

FIG. 34: Finite element simulation of the electrostatic capacitance between a transferred gate stack and graphene. The simulated electrostatic capacitance normalized by graphene channel area is about 359 nF/cm².

FIG. 35: Bilayer graphene for high speed transistors. (a) Theoreical prediction of bandgap opening in bilayer graphene with vertical displacement field. (b) Modulation of the transconductance and on-off ratio in bilayer graphene with application vertical field by a bottom and top gate. (c) Modulation of the transconductance and on-off ratio in bilayer graphene with the application of an electron doping molecule (reduced dibenzyl-bipyridinium) and a single bottom gate. (d,e) Modulation of transconductance, on-off ratio, and Dirac point of bilayer graphene devices. (f) Chemical structure of tetrafluoro-tetracyanoquinodimethane that can be used for hole doping graphene.

FIG. 36: Schematic illustration of the soft-lithography approach to fabricate large array of graphene transistors. (a) Patterned gate array is fabricated on a first substrate with a sacrificial layer. (b) The gate array on the first substrate is laminated onto the large sheet of graphene on a second substrate. (c) The sacrificial layer is removed to release the patterned gate array onto graphene. (d) Similar fabrication process is then applied to obtain large array of graphene transistors. (e,f) Other possible gate geometries (trapezoid or “T”) to simultaneously ensure small channel length and low gate resistance.

### DETAILED DESCRIPTION

### Definitions

The following definitions apply to some of the aspects described with respect to some embodiments of the invention. These definitions may likewise be expanded upon herein.

As used herein, the singular terms “a,” “an,” and “the” include plural referents unless the context clearly dictates otherwise. Thus, for example, reference to an object can include multiple objects unless the context clearly dictates otherwise.

As used herein, the term “adjacent” refers to being near or adjoining. Adjacent objects can be spaced apart from one another or can be in actual or direct contact with one another. In some instances, adjacent objects can be coupled to one another or can be formed integrally with one another.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels or variability of the embodiments described herein.

As used herein, the term “nanometer range” or “nm range” refers to a range of dimensions from about 1 nm to about 1 micrometer (μm). The nm range includes the “lower nm range,” which refers to a range of dimensions from about 1 nm to about 10 nm, the “middle nm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 mm. The μm range includes the “lower μm range,” which refers to a range of dimensions from about 1 μm to about 10 μm, the “middle μm range,” which refers to a range of dimensions from about 10 μm to about 100 μm, and the “upper μm range,” which refers to a range of dimensions from about 100 μm to about 1 mm.

### High Performance Graphene Transistors

Attention first turns to FIG. 1, which sets forth an embodiment of a process for integrating graphene with high-k dielectrics by first synthesizing high-k zirconium oxide (ZrO₂) nanowires at high temperature and then transferring them onto graphene through a dry transfer process at room temperature. This physical assembly approach can allow flexible integration of distinct materials that are normally not compatible, due to material or process incompatibility, and can be used to combine various nanostructures having at least one dimension in the nm range. Exploiting this approach for graphene/dielectric integration preserves the integrity of the graphene lattice and, in some embodiments, affords top-gated graphene devices with transconductance of about 2.0 mS μm⁻¹ (or higher) and a carrier mobility of about 1300 cm²V⁻¹s⁻¹ (or higher). Furthermore, multiple, independently addressable, top-gated graphene transistors can be readily achieved to allow functional circuits.

As will be understood, graphene is an allotrope of carbon, and its structure is typically one-atom-thick sheets of sp²-bonded carbon atoms that are packed in a honeycomb crystal lattice. In the illustrated embodiment, graphene is provided as nanostructures in the form of graphene nanoribbons or thin strips of substantially a monolayer of carbon atoms that can be envisioned as unrolled carbon nanotubes, although a bilayer of graphene is also contemplated. The graphene nanoribbons can be semiconducting due to edge effects and quantum confinement, and can effectively function as a semiconducting channel for FETs. The use of high-k gate dielectrics in the illustrated embodiment can afford high capacitance without relying on ultra-thin film thickness, thereby reducing a gate switching voltage and suppressing direct-tunneling leakage current from a gate. Alternatively, or in combination with ZrO₂, other dielectrics, including other high-k dielectrics having a dielectric constant greater than about 3.9 can be used, such as aluminum oxide (Al₂O₃), hafnium oxide (HfO₂), and other dielectrics having a dielectric constant of at least about 5, such as at least about 9, at least about 12, at least about 15, at least about 18, at least about 20, at least about 23, at least about 27, and up to about 30 (or higher). Also, other types of dielectric nanostructures can be integrated in place of, or in combination with, ZrO₂ nanowires, such as dielectric nanotubes, dielectric nanoribbons, or combinations thereof. Specific examples of other nanostructures include HfO₂ nanowires, Al₂O₃ nanoribbons, nanoribbons including at least one layer of boron nitride (BN), and nanoribbons including a layer of Al₂O₃ and a layer of HfO₂.

FIG. 1 illustrates a process to fabricate top-gated graphene transistors using dielectric nanowires as the high-k gate dielectric. Mechanically peeled graphene flakes or strips on a silicon substrate (or another type of substrate) are used as the starting materials in the illustrated embodiment. Dielectric nanowires are aligned on top of the graphene through a physical dry transfer process, followed by e-beam lithography and metallization process to form the source and drain electrodes (FIG. 1a). It is also contemplated that the dielectric nanowires can be fabricated in-situ on the graphene, in place of a transfer process. The dielectric nanowires extend longitudinally relative to their respective graphene strips. Specifically, alignment of the dielectric nanowires can be carried out such that a lengthwise (or longest dimension) direction of each nanowire is generally aligned with a lengthwise (or longest dimension) direction of a respective graphene strip, such as to within an angular deviation of ±50°, ±40°, ±30°, ±20°, or ±10°. Oxygen-plasma etching is then used to remove exposed graphene, selectively retaining graphene protected by each respective dielectric nanowire and source-drain electrodes (FIG. 1b). An attribute of using nanowire dielectric is that narrow graphene channels (e.g., in the form of graphene nanoribbons) can be automatically defined by the nanowire mask during the oxygen-plasma etching process. A top gate electrode is then formed on top of the dielectric nanowire, with the top gate electrode disposed between the source-drain electrodes (FIG. 1c).

In the illustrated embodiment, a resulting graphene transistor 100 includes a source electrode 102, a drain electrode 104, and a top gate electrode 106, at least one of which includes one or more layers of a metal or another electrically conductive material, such as a layer of titanium (Ti) of about 50 nm in thickness and a layer of Au of about 50 nm in thickness. The source electrode 102 and the drain electrode 104 are spaced apart by a length (L) of a graphene channel 108 extending between and connecting the source electrode 102 and the drain electrode 104. The length of the graphene channel 108 can be in the μm range, such as in the lower or middle μm range, and a width (W) of the graphene channel can be in the nm range, such as in the lower or middle nm range. A ZrO₂ nanowire 110 is disposed on the graphene channel 108, and serves as a top gate dielectric. Similar to the graphene channel 108, a length of the ZrO₂ nanowire 110 can be in the μm range, such as in the lower or middle μm range, and a width or diameter of the ZrO₂ nanowire 110 can be in the nm range, such as in the lower or middle nm range. A highly doped p-type silicon substrate 112 (e.g., <0.004 Ωcm) serves as a back gate, and a 300-nm thermal silicon oxide layer 114 is disposed on the substrate 112, and serves as a back gate dielectric. During operation of the transistor 100, application of a voltage to the top gate electrode 106 controls or modulates a conductivity of the graphene channel 108, thereby controlling or modulating a control flow of charge carriers between the source electrode 102 and the drain electrode 104.

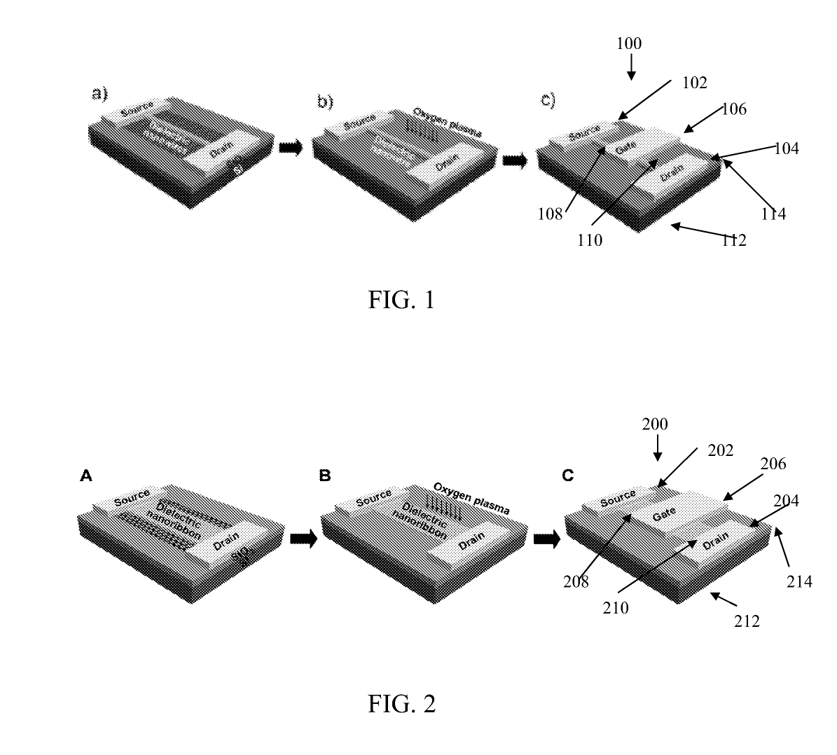

Attention next turns to FIG. 2, which sets forth an embodiment of a process for integrating graphene with high quality, high-k dielectrics using free-standing dielectric nanoribbons. Nanoribbons can be synthesized at high temperature with a crystalline structure substantially free of defects, and then manipulated and assembled at room temperature. This flexibility allows the integration of normally incompatible materials and processes, and can allow new functions in electronics or photonics. In the illustrated embodiment, the dielectric properties of Al₂O₃ nanoribbons are used for graphene-based electronics. Specifically, high quality dielectric Al₂O₃ nanoribbons are first synthesized, and then transferred onto graphene as gate dielectrics for top-gated graphene transistors. This integration approach preserves the pristine nature of the graphene, and, in some embodiments, yields a room temperature carrier mobility of up to about 23,600 cm²/V·s (or higher) in top-gated graphene transistors.

Certain aspects of the embodiment of FIG. 2 can be implemented in a similar manner as previously explained for FIG. 1, and, therefore, those aspects need not be explained again in detail. Although the illustrated embodiment is explained in the context of Al₂O₃, other dielectrics can be integrated in place of, or in combination with, Al₂O₃, including other high-k dielectrics such as ZrO₂ and HfO₂. Also, other types of dielectric nanostructures can be integrated in place of, or in combination with, Al₂O₃ nanoribbons, such as dielectric nanotubes, dielectric nanowires, or combinations thereof.

FIG. 2 illustrates a process to fabricate top-gated graphene transistors. Mechanically peeled graphene flakes or strips on a silicon substrate (or another type of substrate) are used as the starting materials in the illustrated embodiment, although the approach described here can be readily extended to graphene obtained through chemical exfoliation or chemical vapor deposition. Al₂O₃ nanoribbons are aligned on top of the graphene through a physical dry transfer process, followed by e-beam lithography and metallization process to form source and drain electrodes (FIG. 2A). It is also contemplated that the dielectric nanoribbons can be fabricated in-situ on the graphene, in place of a transfer process. Alignment of the dielectric nanoribbons can be carried out such that a lengthwise (or longest dimension) direction of each nanoribbon is generally aligned with a lengthwise (or longest dimension) direction of a respective graphene strip, such as to within an angular deviation of ±50°, ±40°, ±30°, ±20°, or ±10°. Oxygen-plasma etching is then used to remove exposed graphene, selectively retaining graphene protected by each respective dielectric nanoribbon and source-drain electrodes (FIG. 2B). An attribute of using nanoribbon dielectric is that narrow graphene channels (e.g., in the form of graphene nanoribbons) can be automatically defined by the nanoribbon mask during the oxygen-plasma etching process. A top gate electrode is then formed on top of the dielectric nanoribbon, with the top gate electrode disposed between the source-drain electrodes (FIG. 2C).

In the illustrated embodiment, a resulting graphene transistor 200 includes a source electrode 202, a drain electrode 204, and a top gate electrode 206, at least one of which includes one or more layers of a metal or another electrically conductive material, such as a layer of titanium (Ti) of about 50 nm in thickness and a layer of Au of about 50 nm in thickness. The source electrode 202 and the drain electrode 204 are spaced apart by a length (L) of a graphene channel 208 extending between and connecting the source electrode 202 and the drain electrode 204. The length of the graphene channel 208 can be in the μm range, such as in the lower or middle μm range, and a width (W) of the graphene channel 208 can be in the μm range, such as in the lower or middle μm range, or in the nm range, such as the middle or upper nm range. An Al₂O₃ nanoribbon 210 is disposed on the graphene channel 208, and serves as a top gate dielectric. Similar to the graphene channel 208, a length of the Al₂O₃ nanoribbon 210 can be in the μm range, such as in the lower or middle μm range, and a width or diameter of the Al₂O₃ nanoribbon 210 can be in the μm range, such as in the lower or middle μm range, or in the nm range, such as the middle or upper nm range. A thickness of the Al₂O₃ nanoribbon 210 can be in the nm range, such as the middle or upper nm range. A highly doped p-type silicon substrate 212 (e.g., <0.004 Ωcm) serves as a back gate, and a 300-nm thermal silicon oxide layer 214 is disposed on the substrate 212, and serves as a back gate dielectric. During operation of the transistor 200, application of a voltage to the top gate electrode 206 controls or modulates a conductivity of the graphene channel 208, thereby controlling or modulating a control flow of charge carriers between the source electrode 202 and the drain electrode 204.

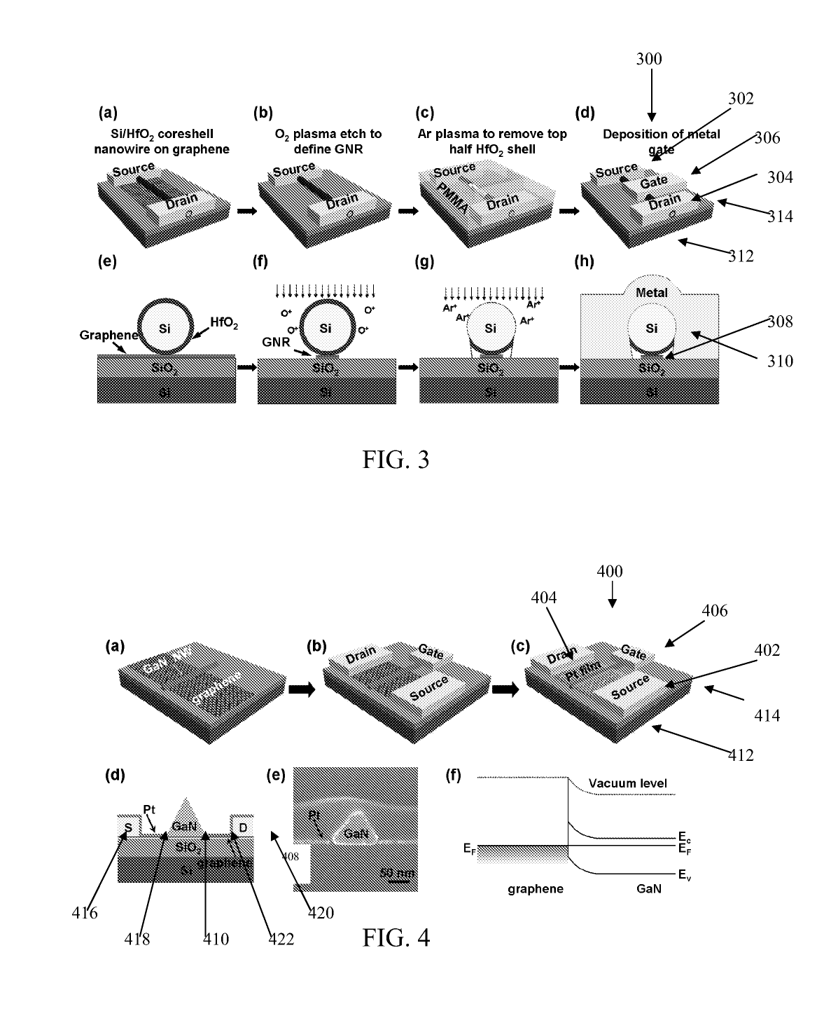

Attention next turns to FIG. 3, which sets forth an embodiment of a process to fabricate top-gated graphene transistors with ultra-thin, high-k dielectrics, by exploiting conductor/dielectric core/shell nanostructures (e.g., nanowires or nanoribbons) as top gates, and in which the high-k dielectrics are deposited on conducting (e.g., a metal, a highly doped semiconductor, or another electrically conductive material) nanostructures using ALD (or another deposition technique) with a precise control of the thickness down to the lower nm range, such as in the range of about 1 nm to about 2 nm. In the illustrated embodiment, Si/HfO₂ core/shell nanowires are synthesized by ALD of HfO₂ on highly doped silicon nanowires. Using such core/shell nanowires as the top gates, graphene transistors are fabricated with the HfO₂ shell as the ultra-thin, gate dielectric and the silicon nanowire core as the self-integrated gate electrode. This approach allows effective integration of ultra-thin, high quality, top gate dielectrics with graphene, and preserves the integrity of the graphene lattice to afford, in some embodiments, graphene devices with a transconductance of about 3.2 mS μm⁻¹ (or higher).

Certain aspects of the embodiment of FIG. 3 can be implemented in a similar manner as previously explained for FIG. 1 and FIG. 2, and, therefore, those aspects need not be explained again in detail. Although the illustrated embodiment is explained in the context of HfO₂, other dielectrics can be integrated in place of, or in combination with, HfO₂, including other high-k dielectrics such as ZrO₂ and Al₂O₃.

FIG. 3 illustrates a process to fabricate top-gated graphene transistors using Si/HfO₂ core/shell nanowires as top gates. The core/shell nanowires are first aligned on top of mechanically peeled graphene flakes or strips on a silicon substrate (or another type of substrate) through a physical dry transfer process, followed by e-beam lithography and metallization process to form source and drain electrodes (FIGS. 3a and e). It is also contemplated that the core/shell nanowires can be fabricated in-situ on the graphene, in place of a transfer process. Alignment of the core/shell nanowires can be carried out such that a lengthwise (or longest dimension) direction of each nanowire is generally aligned with a lengthwise (or longest dimension) direction of a respective graphene strip, such as to within an angular deviation of ±50°, ±40°, ±30°, ±20°, or ±10°. Oxygen-plasma etch is then used to remove exposed graphene, selectively retaining graphene protected underneath each nanowire to form a graphene channel connected to two larger regions of graphene protected under source and drain electrodes (FIGS. 3b and f). An attribute of using core/shell nanowires is that narrow graphene channels (e.g., in the form of graphene nanoribbons) can be automatically defined by the nanowire mask during the oxygen-plasma etching process. To connect a silicon core gate to an external electrode, an upper portion (e.g., the top half) of the dielectric shell is etched away using argon plasma (FIGS. 3c and g), and a top gate electrode is then formed on top of the partially etched nanowire, with the top gate electrode disposed between the source-drain electrodes (FIGS. 3d and h).

In the illustrated embodiment, a resulting graphene transistor 300 includes a source electrode 302, a drain electrode 304, and a top gate electrode 306, at least one of which includes one or more layers of a metal or another electrically conductive material, such as a layer of titanium (Ti) of about 50 nm in thickness and a layer of Au of about 50 nm in thickness. The source electrode 302 and the drain electrode 304 are spaced apart by a length (L) of a graphene channel 308 extending between and connecting the source electrode 302 and the drain electrode 304. The length of the graphene channel 308 can be in nm range, such as the middle or upper nm range, or in the μm range, such as the lower or middle μm range, and a width (W) of the graphene channel 308 can be in the nm range, such as in the lower or middle nm range. A partially etched Si/HfO₂ core/shell nanowire 310 is disposed on the graphene channel 308, and serves as a top gate. Similar to the graphene channel 308, a length of the nanowire 310 can be in the nm range, such as the middle or upper nm range, or in the μm range, such as the lower or middle μm range, and a width or diameter of the nanowire 310 can be in the nm range, such as in the lower or middle nm range. A thickness of the remaining HfO₂ shell (disposed between the graphene channel 308 and the Si core) can be in the nm range, such as the lower or middle nm range. A highly doped p-type silicon substrate 312 (e.g., <0.001 Ωcm) serves as a back gate, and a 300-nm thermal silicon oxide layer 314 is disposed on the substrate 312, and serves as a back gate dielectric. During operation of the transistor 300, application of a voltage to the top gate electrode 306 controls or modulates a conductivity of the graphene channel 308, thereby controlling or modulating a control flow of charge carriers between the source electrode 302 and the drain electrode 304.

Attention next turns to FIG. 4, which sets forth an embodiment of a process for the fabrication of high performance, sub-100 nm channel length graphene transistors using a self-aligned nanowire gate, which is transferred onto graphene through a physical assembly process at room temperature. Source and drain electrodes are formed through a self-alignment process to ensure precise alignment with the nanowire gate. The physical assembly of the nanowire gate preserves the high carrier mobility in graphene, and the self-aligned source-drain electrodes minimize or reduce the contact resistance and, therefore, afford transistors with ultrashort intrinsic delay. In some embodiments, graphene transistors with sub-100 nm channel length can be readily fabricated with a transconductance of about 2.3 mS μm⁻¹ (or higher) and an on-current of about 4.3 mA μm⁻¹ (or higher).

Certain aspects of the embodiment of FIG. 4 can be implemented in a similar manner as previously explained for FIG. 1 through FIG. 3, and, therefore, those aspects need not be explained again in detail. Although the illustrated embodiment is explained in the context of GaN, other semiconductors or other electrically conductive materials can be integrated in place of, or in combination with, GaN, including other highly doped semiconductors. Also, other types of nanostructures can be integrated in place of, or in combination with, GaN nanowires, such as nanotubes, nanoribbons, or combinations thereof.

FIG. 4 illustrates a process to fabricate graphene transistors with self-aligned nanowire gates. In this process, a single layer of graphene flakes or strips are first mechanically peeled onto a highly doped p-type silicon substrate (or another type of substrate) with a 300 nm thermal silicon oxide. Highly doped n-type GaN nanowires are aligned on top of the graphene through a physical dry transfer process (FIG. 4a), followed by e-beam lithography and metallization process to form external source, drain, and gate electrodes (FIG. 4b). It is also contemplated that the nanowires can be fabricated in-situ on the graphene, in place of a transfer process. The nanowires extend transversely relative to their respective graphene strips. Specifically, alignment of the nanowires can be carried out such that a lengthwise (or longest dimension) direction of each nanowire is generally perpendicular to a lengthwise (or longest dimension) direction of a respective graphene strip, such that the two lengthwise directions define an angle in the range of about 60° to about 120°, such as from about 70° to about 110°, from about 80° to about 100°, or from about 85° to about 95°. A thin layer of a Pt metal (or another metal, a highly doped semiconductor, or another electrically conductive material) having a thickness in the nm range, such as the lower or middle nm range or about 10 nm, is then deposited on top of the graphene across the GaN nanowire, with a gap or otherwise an absence of the Pt thin film on an upper portion of the GaN nanowire (e.g., the top half), such that the GaN nanowire separates the Pt thin film into two isolated regions that form the self-aligned source and drain electrodes precisely positioned with the nanowire gate (FIG. 4c-e). In such manner, the GaN nanowire functions as a physical shadow mask to precisely define a placement of the source and drain electrodes relative to the nanowire gate. An attribute of the illustrated embodiment is that graphene channels of short lengths can be defined by a width or a diameter of the GaN nanowires (FIG. 4d-e).

In the illustrated embodiment, a resulting graphene transistor 400 includes a source electrode 402, a drain electrode 404, and a top gate electrode 406, at least one of which includes one or more layers of a metal or another electrically conductive material, such as a layer of titanium (Ti) of about 50 nm in thickness and a layer of Au of about 50 nm in thickness. The source electrode 402 includes a main block portion 416 and an extension portion 418 that extends between the main block portion 416 and a GaN nanowire 410, and the drain electrode 404 includes a main block portion 420 and an extension portion 422 that extends between the main block portion 420 and the GaN nanowire 410. The extension portions 418 and 422 of the source electrode 402 and the drain electrode 404 are spaced apart by a length (L) of a graphene channel 408 corresponding to a width or diameter of the GaN nanowire 410. The length of the graphene channel 408 can be in nm range, such as the lower or middle nm range, and a width (W) of the graphene channel 408 can be in the μm range, such as in the lower or middle μm range. The GaN nanowire 410 is disposed on the graphene channel 408, and serves as a top gate. A length of the nanowire 410 can be in the μm range, such as the lower or middle μm range, and a width or diameter of the nanowire 410 can be in the nm range, such as in the lower or middle nm range. In the illustrated embodiment, a cross-sectional shape of the nanowire 410 is substantially triangular, although other shapes are also contemplated. A highly doped silicon substrate 412 serves as a back gate, and a thermal silicon oxide layer 414 is disposed on the substrate 412, and serves as a back gate dielectric. During operation of the transistor 400, application of a voltage to the top gate electrode 406 controls or modulates a conductivity of the graphene channel 408, thereby controlling or modulating a control flow of charge carriers between the source electrode 402 and the drain electrode 404.

In this device, the contact between graphene and the GaN nanowire 410 creates a Schottky-like potential barrier (FIG. 4f) to prevent or reduce charge leakage between the graphene channel 408 and the GaN nanowire 410, with the interface depletion layer in the GaN nanowire 410 functioning as a “semi-high-k” gate dielectric (k ˜10), and the GaN nanowire 410 itself functioning as the local gate. Of note, the depletion layer dielectric thickness can be controlled by tuning the GaN nanowire 410 doping concentration. Additionally, the GaN nanowire 410 can also form Schottky barrier with the self-aligned source-drain electrodes 402 and 404, which also prevents or reduces the leakage between the gate and the source-drain electrodes 402 and 404.

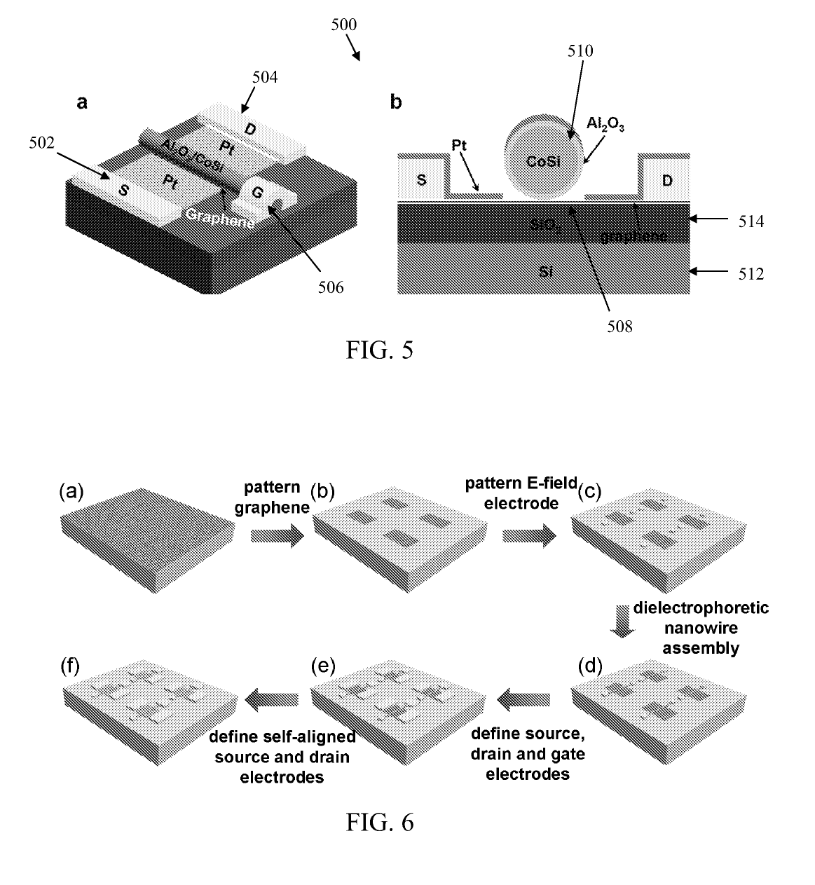

Attention next turns to FIG. 5, which sets forth an embodiment of a process for the fabrication of graphene transistors with self-aligned nanowire gates and improved operation frequencies. The graphene transistors are fabricated using Co₂Si/Al₂O₃ core/shell nanowires as top gates, with source and drain electrodes formed through a self-alignment process, and a channel length defined by a nanowire width or diameter. The physical assembly of the nanowire gate preserves the high carrier mobility in graphene, and the self-aligned process ensures that the edges of the source and drain electrodes are automatically and precisely positioned with the nanowire gate so that no overlapping or significant gaps exist between these electrodes, thereby reducing or minimizing access resistance. In some embodiments, graphene transistors with a channel length down to about 144 nm (or less) can be fabricated with an on-current of about 3.37 mA μm⁻¹ (or higher) and a transconductance of about 1.25 mS μm⁻¹ (or higher). Of note, on-chip microwave measurements demonstrate that the self-aligned devices of some embodiments can exhibit a high short-circuit, current-gain, intrinsic cut-off frequency f_{T} of about 300 GHz (or higher) and a power-gain maximum oscillation frequency fₘₐₓ of about 500 GHz (or higher). As will be understood, another performance characteristic is an extrinsic cut-off frequency, and, unless denoted otherwise herein, a cut-off frequency used herein refers to an intrinsic cut-off frequency.

Certain aspects of the embodiment of FIG. 5 can be implemented in a similar manner as previously explained for FIG. 1 through FIG. 4, and, therefore, those aspects need not be explained again in detail. Although the illustrated embodiment is explained in the context of Al₂O₃, other dielectrics can be integrated in place of, or in combination with, Al₂O₃, including other high-k dielectrics such as ZrO₂ and HfO₂. Also, other types of conductor/dielectric core/shell nanostructures (e.g., nanowires or nanoribbons) can be integrated in place of, or in combination with, Co₂Si/Al₂O₃ core/shell nanowires.

FIG. 5 schematically illustrates a graphene transistor 500 with a self-aligned nanowire gate. To fabricate the device, a graphene flake or strip is first mechanically peeled onto a highly resistive silicon substrate 512 (>18,000 Ωcm) (or another type of substrate) with a 300 nm thermal silicon oxide layer 514. A Co₂Si/Al₂O₃ core/shell nanowire 510 is aligned on top of the graphene through a physical dry transfer process, followed by e-beam lithography, buffered oxide etching to partially remove the Al₂O₃ shell and expose an upper portion of the Co₂Si core (e.g., top half), and metallization (Ti/Au, 70 nm/50 nm) process to form a source electrode 502, a drain electrode 504, and a gate electrode 506. It is also contemplated that the nanowire 510 can be fabricated in-situ on the graphene, in place of a transfer process. Alignment of the nanowire 510 can be carried out such that a lengthwise (or longest dimension) direction of the nanowire 510 is generally perpendicular to a lengthwise (or longest dimension) direction of the graphene strip, such that the two lengthwise directions define an angle in the range of about 60° to about 120°, such as from about 70° to about 110°, from about 80° to about 100°, or from about 85° to about 95°. A thin layer of a Pt metal (or another metal, a highly doped semiconductor, or another electrically conductive material) having a thickness in the nm range, such as the lower or middle nm range or about 10 nm, is then deposited on top of the graphene across the nanowire 510, in which the nanowire 510 separates the Pt thin film into two isolated regions that form the self-aligned source and drain electrodes 502 and 504 precisely positioned in close proximity with the nanowire gate (FIGS. 5a and b). An attribute of the illustrated embodiment is that the Co₂Si/Al₂O₃ core/shell nanowire 510 defines a channel length, with a remaining 5 nm Al₂O₃ shell (or having another thickness in the nm range, such as the lower nm range) functioning as a gate dielectric, and the metallic Co₂Si core functioning as a self-integrated local gate.

In the illustrated embodiment, a length of the nanowire 510 can be in the μm range, such as the lower or middle μm range, and a width or diameter of the nanowire 510 can be in the nm range, such as the middle or upper nm range. In the illustrated embodiment, a cross-sectional shape of the nanowire 510 is substantially spherical, although other shapes are also contemplated. A length (L) of a graphene channel 508 can be in nm range, such as the lower or middle nm range, and a width (W) of the graphene channel 508 can be in the μm range, such as in the lower or middle μm range. During operation of the transistor 500, application of a voltage to the top gate electrode 506 controls or modulates a conductivity of the graphene channel 508, thereby controlling or modulating a control flow of charge carriers between the source electrode 502 and the drain electrode 504.

Attention next turns to FIG. 6, which sets forth an embodiment of a process for the fabrication of graphene transistors on a glass substrate through a self-aligned process by using chemical vapor deposition (CVD) grown graphene and a dielectrophoretic assembled nanowire gate array. The self-aligned process allows high performance to be achieved in CVD graphene transistors, with a transconductance of about 0.36 mS/μm (or higher) for some embodiments. The use of a glass substrate (or another insulating substrate) minimizes or reduces a parasitic capacitance (compared to highly resistive silicon or semi-insulating silicon carbide substrate), and allows graphene transistors with a high extrinsic cut-off frequency of greater than or equal to about 50 GHz. The excellent extrinsic cut-off frequency readily allows configuring the graphene transistors into frequency doubling or mixing circuits functioning in the 1-10 GHz regime.

Certain aspects of the embodiment of FIG. 6 can be implemented in a similar manner as previously explained for FIG. 1 through FIG. 5, and, therefore, those aspects need not be explained again in detail. Although the illustrated embodiment is explained in the context of nanowires, other types of nanostructures can be integrated in place of, or in combination with, nanowires, such as nanotubes, nanoribbons, or combinations thereof.

The fabrication process flow is shown in FIG. 6. A single layer of graphene is first grown by CVD, and transferred onto a glass substrate (or another type of substrate) (FIG. 6a). The graphene is then patterned using photolithography followed by oxygen-plasma treatment to form isolated graphene strips (FIG. 6b). Next, pairs of electrodes are defined across each graphene strip (FIG. 6c), and a dielectrophoresis assembly process is then used to precisely position a nanowire on top of each patterned graphene strip and extending across each pair of electrodes (FIG. 6d). The dielectrophoresis process is a self-limiting process allowing assembly of a single nanowire on each pair of electrodes with high yield by controlling hydrodynamic and electric field forces. Alignment of the nanowire can be carried out such that a lengthwise (or longest dimension) direction of the nanowire is generally perpendicular to a lengthwise (or longest dimension) direction of the graphene strip, such that the two lengthwise directions define an angle in the range of about 60° to about 120°, such as from about 70° to about 110°, from about 80° to about 100°, or from about 85° to about 95°. Lithography and metallization (Ti/Au, 70 nm/50 nm) processes are then used to form external source, drain and gate electrodes (FIG. 6e). Lastly, a thin layer of a Pt metal (or another metal, a highly doped semiconductor, or another electrically conductive material) having a thickness in the nm range, such as the lower or middle nm range or about 10 nm, is deposited on top of the graphene across each nanowire, in which the nanowire separates the Pt thin film into two isolated regions that form the self-aligned source and drain electrodes adjacent to the nanowire gate (FIG. 6f).

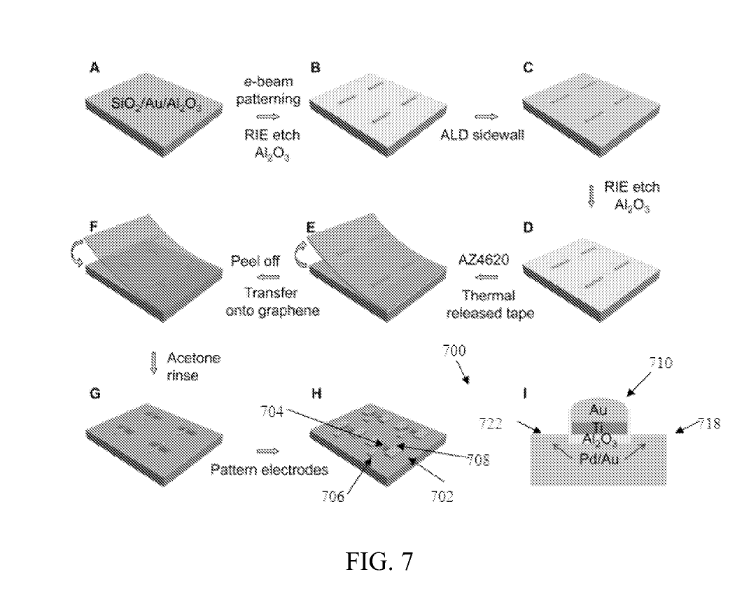

Attention next turns to FIG. 7, which sets forth an embodiment of a scalable process for the fabrication of graphene transistors by transferring lithography patterned gate stacks onto CVD grown graphene as self-aligned top gates. Specifically, arrays of gate stacks are first patterned on a sacrificial substrate, and then transferred onto arbitrary substrates with graphene on top. A self-aligned process, facilitated by a structure of the gate stack, is used to precisely position source and drain electrodes with minimized or reduced access resistance or parasitic capacitance. In some embodiments, high performance, top-gated, CVD graphene transistors can be fabricated with a transconductance of about 0.53 mS/μm (or higher) and an on-current density of about 1.73 mA/μm (or higher). With this approach, some embodiments can achieve a high cut-off frequency in both CVD graphene (up to about 212 GHz or higher) and peeled graphene (up to about 427 GHz or higher).

Certain aspects of the embodiment of FIG. 7 can be implemented in a similar manner as previously explained for FIG. 1 through FIG. 6, and, therefore, those aspects need not be explained again in detail. Although the illustrated embodiment is explained in the context of nanowires, other types of nanostructures can be integrated in place of, or in combination with, nanowires, such as nanotubes, nanoribbons, or combinations thereof.

FIG. 7 illustrates a process to fabricate self-aligned graphene transistors with transferred gate stacks. A thin layer of Au (or another metal, a highly doped semiconductor, or another electrically conductive material) having a thickness in the nm range, such as the lower or middle nm range or about 50 nm, is first deposited on a Si/SiO₂ substrate (or another type of substrate) by e-beam evaporation. This gold film serves as a sacrificial substrate in the transferring process. Sequentially, various layers of a gate stack including a layer of Al₂O₃, a layer of Ti, and a layer Au (or other combinations of layers of dielectrics, metals, highly doped semiconductors, or other electrically conductive materials) are sequentially formed on top of the gold film by ALD, lithography, and reactive ion etch (RIE) processes (FIG. 7A, B). A gate sidewall spacer is formed by depositing a thin layer of Al₂O₃ (or another dielectric) using ALD (FIG. 7C), followed by an anisotropic RIE process to etch away unwanted Al₂O₃ on a top surface of the gate stack and the substrate (FIG. 7D). Because of the limited affinity between the sacrificial Au film and the underneath SiO₂, the fabricated gate stacks are readily peeled off by a thermal release tape. Additionally, to facilitate peeling off and releasing, a thin layer of a polymer that has a glass transition temperature close to the thermal tape releasing temperature is spin-coated before peeling off the gate stacks. Therefore, the patterned top gate stacks are sandwiched between the gold film and the polymer layer for peeling off from the substrate (FIG. 7E). After Au etching, the gate stacks can be readily transferred onto a desired graphene substrate through a thermal releasing process (FIG. 7F). Compared to another releasing method such as lateral undercut etching of the underneath sacrificial layer, this mechanical peeling is faster and incurs lower damage or contamination to the releasing structure. Moreover, the flexible nature of the approach is compatible with roll-to-roll transfer process, rendering it applicable for printable electronics. The CVD graphene is grown on a copper foil and transferred onto an arbitrary substrate to yield the graphene substrate. After transferring the gate stacks, external source, drain, and gate electrodes are formed by lithography and metallization process. Alignment of the gate stacks can be carried out such that a lengthwise (or longest dimension) direction of each gate stack is generally perpendicular to a lengthwise (or longest dimension) direction of a respective graphene strip, such that the two lengthwise directions define an angle in the range of about 60° to about 120°, such as from about 70° to about 110°, from about 80° to about 100°, or from about 85° to about 95°. Finally, a thin layer of a metal or another electrically conductive material is deposited (or multiple layers of different metals or electrically conductive materials, such as Pd and Au having respective thicknesses of about 5 nm and about 10 nm) to form self-aligned source and drain electrodes, which are separated by the gate spacer dielectric (FIG. 7H, I). This fabrication approach is intrinsically scalable, and is compatible with various substrates such as Si, glass, and polymer substrates.

In the illustrated embodiment, a resulting graphene transistor 700 includes a source electrode 702, a drain electrode 704, and a top gate electrode 706. The source electrode 702 includes a main block portion and an extension portion 718 that extends between the main block portion and a gate stack 710, and the drain electrode 704 includes a main block portion and an extension portion 722 that extends between the main block portion and the gate stack 710. The extension portions 718 and 722 of the source electrode 702 and the drain electrode 704 are spaced apart by a length (L) of a graphene channel 708 corresponding to a width of the gate stack 710. The length of the graphene channel 708 can be in nm range, such as the lower or middle nm range, and a width (W) of the graphene channel 708 can be in the μm range, such as in the lower or middle μm range. The gate stack 710 is disposed on the graphene channel 708, and serves as a top gate. In the illustrated embodiment, the gate stack 710 includes a layer of Al₂O₃ (or another dielectric) serving as the top gate dielectric, a layer of Ti (or another metal or other electrically conductive material), and a layer of Au (or another metal or other electrically conductive material), at least one of which has a thickness in the nm range, such as the lower or middle nm range. The gate stack 710 also includes a sidewall spacer of Al₂O₃ (or another dielectric), which at least partially covers sidewalls (e.g., opposing sidewalls facing the extension portions 718 and 722) of the layer of Ti and the layer of Au, while leaving a top surface of the layer of Au exposed. During operation of the transistor 700, application of a voltage to the top gate electrode 706 controls or modulates a conductivity of the graphene channel 708, thereby controlling or modulating a control flow of charge carriers between the source electrode 702 and the drain electrode 704.

Other implementations of the gate stack 710 are contemplated, such as an “inverted trapezoid” gate structure or a “T” gate structure. Such gate structures can be desirable for high speed devices to simultaneously achieve a short gate length and a low gate resistance.

Advantageously, resulting top-gated graphene transistors according to various embodiments of the invention, such as those fabricated according to FIG. 1 through FIG. 7, can exhibit a number of improved performance characteristics. For example, a graphene transistor can have a high on-current (Iₒₙ) of at least about 1 mA μm⁻¹, such as at least about 1.2 mA μm⁻¹, at least about 1.5 mA μm⁻¹, at least about 1.7 mA μm⁻¹, at least about 2 mA μm⁻¹, or at least about 2.5 mA μm⁻¹, and up to about 5 mA μm⁻¹ (or higher), such as up to about 4 mA μm⁻¹, up to about 3.6 mA μm⁻¹, or up to about 3.2 mA μm⁻¹, as scaled by a width (W) of a graphene channel and as measured, for example, at a drain-source voltage (V_{ds}) of about 1 V and a top gate voltage (V_{TG}) of about −1 V (or as measured at V_{ds} of about 1 V and V_{TG} of about −1.5 V, as measured at V_{ds} of about 1 V and V_{TG} of about −0.5 V, or as measured at V_{ds} of about −1 V and V_{TG} of about 0 V). As another example, a graphene transistor can have a high peak (or maximum) transconductance (gₘ) of at least about 0.3 mS μm⁻¹, such as at least about 0.35 mS μm⁻¹, at least about 0.8 mS μm⁻¹, at least about 1 mS μm⁻¹, at least about 1.25 mS μm⁻¹, at least about 1.8 mS μm⁻¹, at least about 2 mS μm⁻¹, or at least about 2.3 mS μm⁻¹, and up to about 5 mS μm⁻¹ (or higher), such as up to about 4 mS μm⁻¹, up to about 3.5 mS μm⁻¹, or up to about 3.2 mS μm⁻¹, as scaled by W and as measured, for example, at V_{ds} of about 1 V or about −1 V. As another example, a graphene transistor can have a high carrier mobility of at least about 1000 cm²V⁻¹s⁻¹, such as at least about 1200 cm²V⁻¹s⁻¹, at least about 1300 cm²V⁻¹s⁻¹, at least about 1800 cm²V⁻¹s⁻¹, at least about 2000 cm²V⁻¹s⁻¹, at least about 5000 cm²V⁻¹s⁻¹, at least about 8000 cm²V⁻¹s⁻¹, at least about 10,000 cm²V⁻¹s⁻¹, at least about 12,000 cm²V⁻¹s⁻¹, at least about 15,000 cm²V⁻¹s⁻¹, at least about 18,000 cm²V⁻¹s⁻¹, at least about 20,000 cm²V⁻¹s⁻¹, or at least about 22,000 cm²V⁻¹s⁻¹, and up to about 40,000 cm²V⁻¹s⁻¹ (or higher), such as up to about 30,000 cm²V⁻¹s⁻¹, up to about 28,000 cm²V⁻¹s⁻¹, or up to about 26,000 cm²V⁻¹s⁻¹.

### EXAMPLES

The following examples describe specific aspects of some embodiments of the invention to illustrate and provide a description for those of ordinary skill in the art. The examples should not be construed as limiting the invention, as the examples merely provide specific methodology useful in understanding and practicing some embodiments of the invention.

### Example 1

Top-gated graphene transistors were fabricated according to the process shown in FIG. 1. Specifically, graphene strips (e.g., in the form of graphene nanoribbons) were integrated with high-k dielectrics by first synthesizing high-k ZrO₂ nanowires at high temperature and then transferring them onto graphene through a dry transfer process at room temperature.

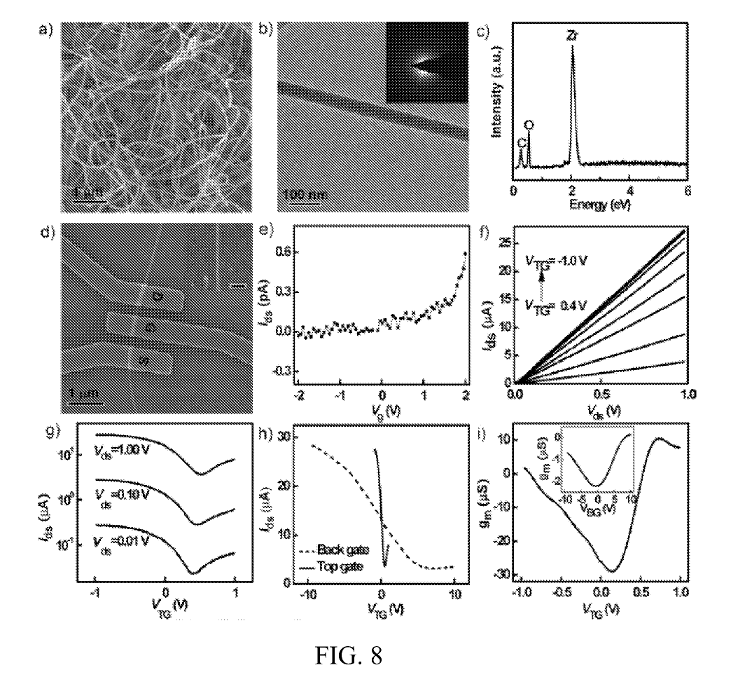

Zirconium oxide (ZrO₂) is an excellent high-k dielectric material with multiple desirable characteristics, including a high dielectric constant (˜23), a wide bandgap (5.1-7.8 eV), and good thermal stability. ZrO₂ nanowires were grown at about 1000° C. through a chemical vapor deposition process in a tube furnace with ZrCl₄ powders as the precursor. A scanning electron microscopy (SEM) image shows that ZrO₂ nanowires are about several tens of micrometers in length and about 40 nm-100 nm in diameter (FIG. 8a). Transmission electron microscopy (TEM) and selected area electron diffraction (SAED) studies reveal that ZrO₂ nanowires are amorphous (FIG. 8b and inset). Energy dispersive X-ray (EDX) analysis of the nanowires detected zirconium and oxygen signals in the substantial absence of other signals, suggesting high purity of the ZrO₂ nanowires (FIG. 8c).

In the fabrication, a ZrO₂ nanowire functions as a nanoscale etch mask to define a narrow graphene strip with a width of about 10 nm-20 nm through aggressive over etching (FIG. 8d, inset) as well as a top gated dielectric for the resulting graphene transistor (FIG. 8d). Electrical transport studies of the top-gated device were carried out under an ambient condition at room temperature. Before starting transistor characterization, testing was carried out for the gate leakage across the ZrO₂ dielectric nanowire. Of note, the tunneling leakage current between a top gate and a graphene channel was negligible in the top gate voltage range of ±2 V (FIG. 8e). This measurement demonstrates that the ZrO₂ dielectric nanowire can function as an effective gate insulator for top-gated graphene transistors.

The drain-source current (I_{ds}) versus drain-source voltage (V_{ds}) plot at various top gate voltages (V_{TG}) shows the graphene transistor output characteristics (FIG. 8f). The device conductance decreased as the gate potential increased towards positive direction and increased as the gate potential increased towards negative direction, suggesting that the graphene strip was p-doped, which can be attributed to edge oxidation or physisorbed O₂ from ambient conditions or the device fabrication process. The output characteristics show that the device can deliver an on-current of about 28 mA at V_{ds}=1 V and V_{TG}=−1 V (FIG. 8f).

FIG. 8g shows the transfer characteristics of the drain-source current I, versus the top gate voltage V_{TG} curves for the same device at different drain-source voltages. The device shows a room temperature on/off ratio of about 12 at V_{ds}=0.1 V, consistent with a graphene strip with an estimated width of about 15 nm. To evaluate top-gated devices versus conventional back-gated devices, transfer characteristics were measured in both the top-gated configuration (I_{ds}−V_{TG}) and back-gated configuration (I_{ds}−V_{BG}; FIG. 8h). Of note, the gate-voltage swing to achieve a similar current modulation in the top-gated configuration is more than one order of magnitude smaller than that in the back-gated configuration. Transfer characteristics show that a top-gated graphene transistor using a ZrO₂ nanowire dielectric can be switched on and off with a small gate voltage swing of about 1 V (solid curve in FIG. 8h), in contrast to 10 V-40 V for the back-gated configuration (dashed curve in FIG. 8h). The transconductance gₘ=dI_{ds}/dV_{TG} of the device can be extracted from the I_{ds}−V_{TG} curve. The gₘ at V_{ds}=0.1 V is about 29 mS in the top-gated configuration (FIG. 8i), more than about 12 times larger than that of the back-gated configuration (about 2.3 mS, see the inset in FIG. 8i).

To further understand the device performance, studies were carried out to determine the gate capacitance, which is not straightforward due to the complex geometry. To this end, a three-dimensional finite element method was used to calculate the capacitance of the device, which yields an electrostatic capacitance (Cₑ) of about 1170 nFcm⁻² for a 15-nm graphene strip under a 50 nm ZrO₂ nanowire. Taking the top gate capacitance (Cₜₒₚ) as being the serial combination of the Cₑ and the quantum capacitance (C_{q}), one obtains Cₜₒₚ=(C_{q}Cₑ)/(Cₑ+C_{q})=about 738 nFcm⁻², assuming C_{q} of about 2000 nFcm⁻². Based on a standard transistor model, the hole mobility is calculated as μ=(gₘ L)(Cₜₒₚ V_{ds} W)˜1310 cm²V⁻¹s⁻¹, which is higher that other reported values for graphene devices.

Studies were also carried out to compare the top-gated graphene devices with state-of-the-art silicon metal oxide semiconductor field-effect transistors (MOSFETs). The effective on-current Iₒₙ for a field-effect transistor (FET) is typically characterized at V_{ds}=V_{g(on-off)}=V_{dd}, where V_{g(on-off)} is the gate-voltage swing from the off to the on state, and V_{dd} is the power supply voltage. Considering V_{ds}=V_{g(on-off)}=V_{dd}=1 V, the Iₒₙ of the top-gated graphene device at V_{ds}=1 V and 1V gate swing from the off state is about 25 mA. Taking the channel width of the graphene strip as about 15 nm, the scaled values of Iₒₙ and gₘ of the graphene device are about 1.7 mA μm⁻¹ and about 2.0 mS μm⁻¹, already exceeding the values of 0.7 mA μm⁻¹ and 0.8 mS μm⁻¹ in sub-100 nm silicon p-MOSFETs and comparable to those of n-MOSFET devices employing high-k dielectrics. This is noteworthy because high transconductance is desirable for transistor performance and voltage gains of transistor-based devices including amplifiers and logic gates.

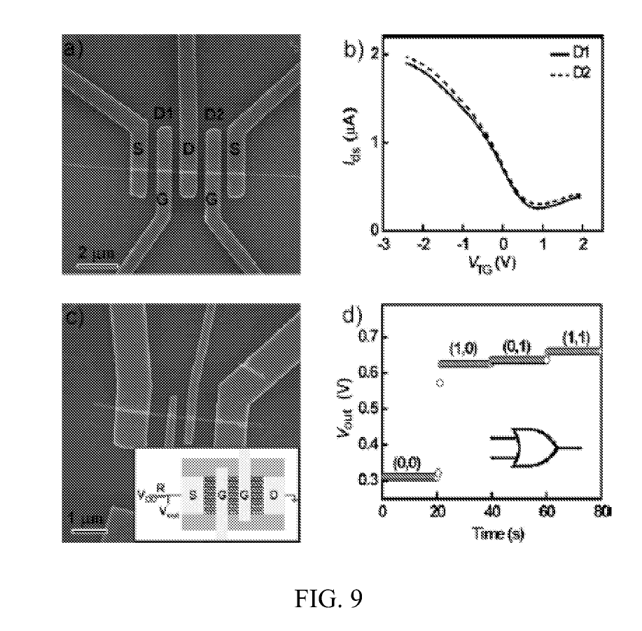

These studies demonstrate that ZrO₂ nanowires can function as effective gate dielectrics for high performance, top-gated graphene devices. It should be noted that the fabricated device has a relatively large channel length (˜500 nm) and a relatively large dielectric thickness (ZrO₂ nanowire diameter ˜50 nm). It is reasonable to expect that the on-current and transconductance can be further improved by shrinking the channel length and decreasing the dielectric nanowire diameter. With smaller nanowires, it is expected that top-gated devices with higher on/off ratios can be achieved. Furthermore, with the top-gated devices, multiple graphene FETs and FET arrays can be readily fabricated with independently addressable top gates (FIG. 9a and FIG. 9b), and therefore allowing for diverse electronic functions. For example, a logic OR gate is obtained with two independent gate electrodes fabricated on a graphene strip in conjunction with a loading resistor (FIG. 9c). The OR function occurs because the output voltage is low when the inputs to both gates are at low voltages (FIG. 9d). When one or both gates are at high voltages, the graphene channel is electrically shut off, resulting in a high output voltage.

In summary, this example demonstrates a strategy to integrate high-k dielectrics for top-gated graphene transistors. Using the high-k oxide nanowires as the gate dielectrics and etch mask, high performance, top-gated graphene transistors have been fabricated with high transconductance (29 mS per graphene strip, 2 mS mm⁻¹) and high mobility (˜1300 cm²V⁻¹s⁻¹). With the top-gated devices, an independently addressable graphene device array and a logic OR gate have also been demonstrated. This strategy opens a new avenue to integrate high-k dielectrics on graphene. With further optimization of the dielectric nanowire growth and the assembly process to precisely control their physical dimension and spatial location, large arrays of top-gated graphene transistors or circuits can be implemented.

Synthesis and Characterization of ZrO₂ Nanowires:

ZrO₂ nanowires were grown at about 1000° C. by a chemical vapor deposition process in a tube furnace with ZrCl₄ powders as the precursor. In brief, the ZrCl₄ powder in a quartz boat was placed upstream with a temperature of about 200° C., and a piece of silicon, the deposition substrate, was placed at the center of the tube furnace at a temperature of about 1000° C. Form gas (5% H₂ in Ar) with a flow rate of 200 sccm was used as the carrier gas and the reaction medium. The temperature was maintained for 2 h, followed by naturally cooling to room temperature. The microstructures and morphologies of the ZrO₂ nanowires were characterized by a JEOL 6700 SEM instrument. The lattice image of the ZrO₂ nanowires was observed by an FEI Titan high-resolution TEM (HRTEM) instrument with EDX spectroscopy. The lengths and diameters of the nanowires were obtained using atomic force microscopy (AFM, Veeco Dimension 5000).

Contact Printing of Nanowires on Graphene:

The overall process involves the physical transfer of ZrO₂ nanowires directly from a nanowire growth substrate to a graphene substrate via contact printing. Specifically, a graphene device substrate was first firmly attached to a bench top, and the nanowire growth substrate was placed upside down on top of the graphene substrate, such that the nanowires were in contact with the graphene. A gentle manual pressure was then applied from the top, followed by slightly sliding the growth substrate. The ZrO₂ nanowires were aligned by sheer forces during the sliding process. This process resulted in the direct dry transfer of ZrO₂ nanowires from the growth substrate to the graphene substrate. The sample was then rinsed with isopropanol, followed by nitrogen blow-dry, in which the capillary drying process near the nanowires can contribute toward the nanowires being firmly attached to the graphene substrate surface.

Top-Gated Graphene Transistor Fabrication and Characterization:

Oxygen plasma (Diener Electronic) was used to selectively etch away the unprotected graphene region and leave graphene strips underneath the ZrO₂ nanowire-mask protection. The etching time was about 160 s at a power level of about 40 W. The electrical transport properties were measured by a Lakeshore probe station with a customized data acquisition system in ambient condition at room temperature.

### Example 2

Top-gated graphene transistors were fabricated according to the process shown in FIG. 2. Specifically, high quality dielectric Al₂O₃ strips were first synthesized, and then transferred onto graphene as the gate dielectrics for top-gated graphene transistors.

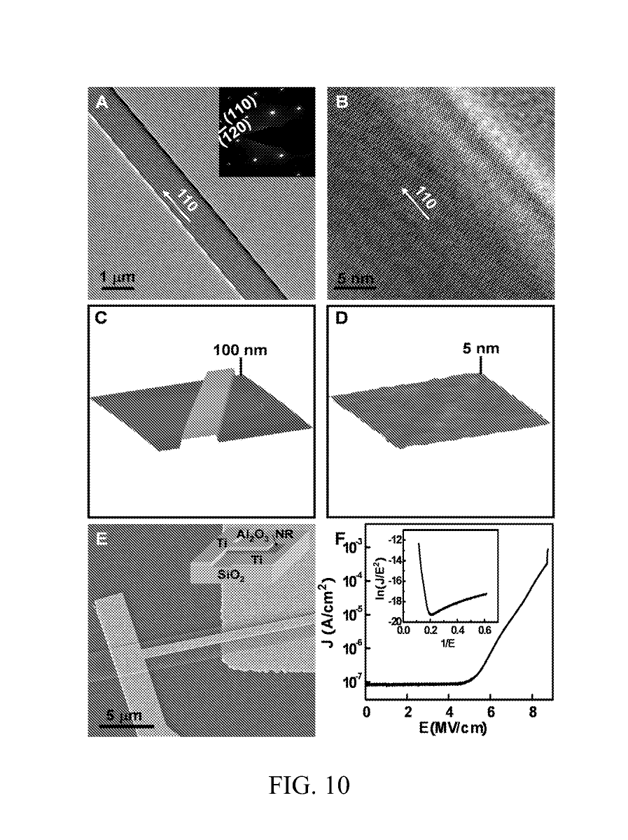

Aluminum oxide (Al₂O₃), with a dielectric constant of about 9.1, is a desirable high-k material with excellent dielectric properties, as well as thermal and chemical stability. In the studies set forth in this example, Al₂O₃ strips (e.g., in the form of nanoribbons) were used to demonstrate the strategy of using pre-formed, free-standing strips as the top-gate dielectrics. Al₂O₃ strips were synthesized through a physical vapor transport approach at about 1200° C. TEM studies show that the Al₂O₃ strips typically have a width of about 1-3 microns, and a length on the order of 10 microns (FIG. 10A). SAED study shows the nanoribbon has a single crystalline α-Al₂O₃ structure, oriented along <110> direction in its long axis, and along <001> direction (c-plane) in its thickness (inset, FIG. 10A). The high resolution TEM image (HRTEM) confirms that the nanoribbon is a single crystal with substantially perfect crystalline structure free of any noticeable defects (FIG. 10B). AFM studies show the nanoribbons typically have a thickness of about 15 nm-150 nm (FIG. 10C), and a substantially atomically smooth surface with root mean square roughness less than about 0.2 nm (FIG. 10D).

To understand the intrinsic dielectric properties of the nanoribbons, we have fabricated metal-insulator-metal (MIM) devices (FIG. 10E) to characterize the current tunneling, breakdown and dielectric characteristics. Electrical measurements of the MIM device show that current density (J) vs. electric field (E) relation exhibits typical Fowler-Nordheim (F-N) tunneling behavior with a breakdown field of about 8.5 MV/cm (FIG. 10F and inset), comparable to the best quality ALD Al₂O₃ film. This type of field-assisted tunneling can be described by charge carrier tunneling through a triangular barrier with:

J=AE_{OX}²exp(−B/E_{OX})
where A=1.54×10⁻⁶(1/(m*Φ_{B})
and B=6.83×10⁷(m*)^{1/2}(Φ_{B})^{3/2}

J is current density, Eₒₓ is the oxide electric field, m* is the effective mass of the charge carrier, which is about 0.23 mₑ, and Φ_{B} is the barrier height. Fitting the J-E characteristics with F-N tunneling model gives a tunnel barrier of about 2.0 eV between Al₂O₃ and Ti, comparable to previous reports of the barrier height between ALD Al₂O₃ and metals of similar work. The relative dielectric constant is also determined from capacitance-voltage measurement as 8.5, which is larger than typical values observed in ALD Al₂O₃ films. These studies demonstrate that the Al₂O₃ nanoribbons have dielectric properties comparable to, or better than, the best quality ALD Al₂O₃ film, and can function as an excellent dielectric material for top-gated graphene transistors.

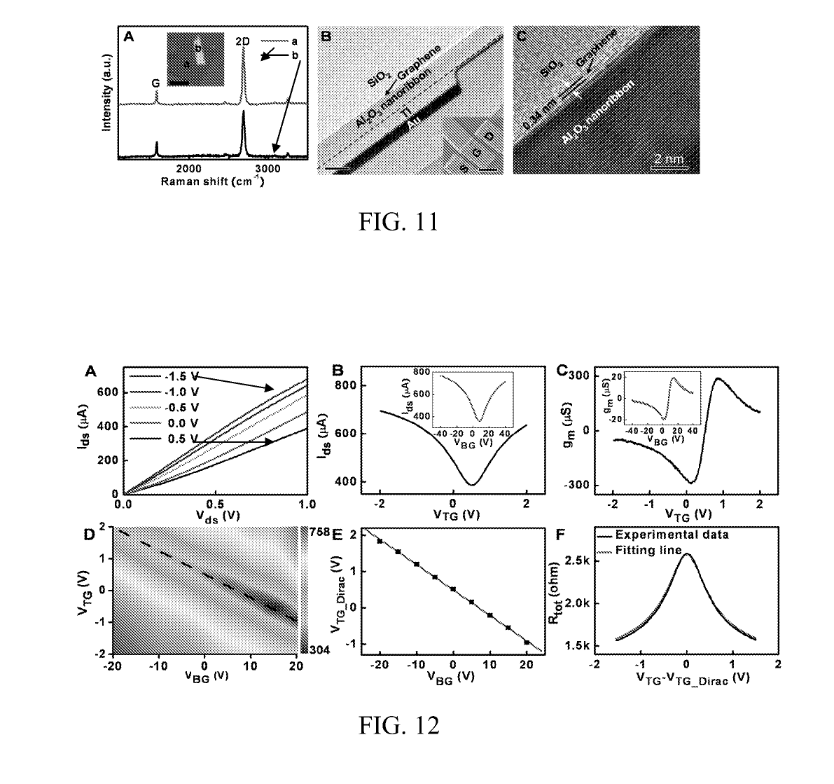

The Al₂O₃ nanoribbons can be aligned onto the top of the graphene through a physical transfer process. Previous studies have shown that the deposition of oxide on top of graphene often introduces significant defects into the graphene structure with a noticeable defect band (D-band) emerging around 1350 cm⁻¹ in Raman spectra. To this end, micro-Raman spectroscopy was used to investigate the interaction between an Al₂O₃ nanoribbon and the underlying graphene (inset, FIG. 11A). Micro-Raman spectra were collected from bare graphene (point a) and Al₂O₃ nanoribbon covered graphene (point b). Of note, there is no clear difference between the two Raman spectra, and there is no noticeable D-band (FIG. 11A), in contrast to previous studies.

The excellent dielectric properties observed in the single crystalline α-Al₂O₃ nanoribbons readily allows their incorporation as the gate dielectrics for top-gated graphene transistors (inset, FIG. 11B). Cross-section TEM was used to study the graphene-dielectric interface (FIG. 11B and FIG. 11C). The gate stack (SiO₂/graphene/Al₂O₃/Ti/Au) can be observed in FIG. 11B. The high resolution TEM image of the device shows that the graphene layers are intimately integrated with the crystalline Al₂O₃ nanoribbon without any noticeable gap or impurities between them (FIG. 11C). Together, these studies demonstrate that the physical assembly approach can effectively integrate Al₂O₃ nanoribbon with graphene without introducing any appreciable defects into the graphene lattice, and thus can effectively preserve the high carrier mobility in the resulting devices.

The electrical transport studies of the top-gated graphene transistors were carried out at room temperature. FIG. 12A shows the drain-source current (I_{ds}) versus drain-source voltage (V_{ds}) output characteristics of the transistor at various top gate voltage (V_{TG}) of −1.5, −1.0, −0.5, 0.0, and 0.5 V. The device delivers an on-current of about 675 μA at V_{ds}=1 V and V_{TG}=−1.5 V. To evaluate the top-gated devices versus conventional back-gated devices, measurements were made of the transfer characteristics, I_{ds}, vs. top gate voltage (V_{TG}) and back gate voltage (V_{BG}) (FIG. 12B and inset). Of note, the gate voltage swing to achieve similar current modulation in top-gated configuration is more than one order of magnitude smaller than that in the back-gated configuration. The transconductance gₘ=dI_{ds}/dV_{TG} can be extracted from the I_{ds}−V_{TG} curve (FIG. 12C). At V_{ds}=1 V, the top-gated device exhibits a maximum gₘ of about 290 μS, which is about 15 times larger than that of the back-gated configuration (gₘ˜19.5 μS).

FIG. 12D further shows a two-dimensional plot of the device conductance as a function of varying V_{BG} and V_{TG} bias, from which the top gate Dirac point (V_{TG}_{_{—}}_{Dirac}) shift can be determined as a function of V_{BG} (FIG. 12E). The result gives the ratio between top gate and back gate capacitances, C_{TG}/C_{BG}≈14.3. This gate capacitance ratio is consistent with the improvement factor (˜15) in transconductance of top- vs. back-gated configurations. Using the back gate capacitance value of C_{BG}=11.5 nF/cm², the top gate capacitance is estimated to be C_{TG}=164.5 nF/cm², corresponding to a relative dielectric constant of about 8.4 for Al₂O₃ nanoribbon (which is consistent with the value obtained from MIM devices).

To further gauge the transistor performance, studies were carried out to determine the carrier mobility. To accurately derive the mobility value, it is desirable to exclude the contact resistance, which is comparable to the graphene transistor channel resistance. The total resistance of the device can be expressed as the following:

$${R}_{tot} = {R}_{contact} + {R}_{channel} = {R}_{contact} = \frac{L / W}{ne μ}$$

where R_{channel} is the resistance of the graphene channel covered by the top gate electrode, the contact resistance R_{contact} includes the uncovered graphene portion resistance and the metal/graphene contact resistance, L is the channel length, W is the channel width, and n is the carrier concentration in the graphene channel region, which can be approximated by the following equation:

n=\sqrt{n₀²+n_{TG}²}={square root over (n₀²+((C_{TG}(V_{TG}−V_{TG}_{_{—}}_{Dirac})/e)²)}

where n₀ is residual carrier concentration, representing the density of carriers at Dirac point; n_{TG}=C_{TG}(V_{TG}−V_{TG}_{_{—}}_{Dirac})/e is the carrier concentration induced by the top gate bias away from the Dirac point, C_{TG} can be approximated by the oxide capacitance of 164.5 nF cm⁻² (the quantum capacitance is neglected here as it is more than one order of magnitude larger at ˜2000 nF cm⁻²).

By fitting this model to the measured data in FIG. 12B, the relevant parameters, n₀, R_{contact} and μ can be extracted. FIG. 12F shows the measured Rₜₒₜ versus V_{TG}, along with the fitted curve derived the equation. The fitted curve agrees well with the experimental data, with a single value of the residual concentration n₀=4.1×10¹¹ cm⁻², R_{contact}˜1240Ω, and the mobility μ=22,400 cm²/V·s. The fitted contact resistance R_{contact}=˜1240Ω is comparable to the R_{contact} determined by four-probe measurements of similar devices. The mobility value derived from top-gated configuration is also consistent with that obtained from back-gated measurement (25,600 cm²/V·s). Studies were carried out for multiple devices fabricated with the same approach, all of which exhibited carrier mobilities well exceeding 10,000 cm²/V·s (Table 1), comparable to the best reported values in back-gated devices and about one order of magnitude better than typical values previously reported for top-gated devices. The variation in mobility values is commonly seen in graphene-based devices, which may be attributed to variable local environment with different local potential, defects, impurities or stress. Together, these studies demonstrate that the presence of Al₂O₃ nanoribbon on top of graphene does not lead to any noticeable mobility degradation, in contrast to previous efforts in using ALD or PVD to deposit dielectrics on graphene.

TABLE 1
The mobility values observed in multiple top-gated
graphene transistors with variable Al₂O₃ thickness.

| Device No. | 1 | 2 | 3 | 4 | 5 | 6 | 7 | 8 | 9 |
|---|---|---|---|---|---|---|---|---|---|
| Thickness | 38 | 45 | 48 | 50 | 60 | 65 | 75 | 82 | 150 |
| (nm) | | | | | | | | | |
| Mobility | 23600 | 22400 | 18200 | 22600 | 11200 | 15300 | 21100 | 11800 | 13300 |
| (cm²/V · s) | | | | | | | | | |

In conclusion, a strategy has been demonstrated to integrate pristine graphene with high quality high-k dielectrics by physically assembling free-standing oxide nanoribbons. Using the Al₂O₃ nanoribbons as the gate dielectrics, the top-gated graphene transistors have been fabricated to exhibit superior performance with high carrier mobility. This strategy opens a new avenue to integrate high-k dielectrics on graphene with the preservation of high carrier mobility. With further optimization of nanoribbon growth and assembly process to precisely control their physical dimension and spatial location, large arrays of top-gated graphene transistors or circuits can be implemented. This physical assembly and integration approach can thus open a new avenue to high performance graphene electronics to impact broadly from high frequency high speed circuits to flexible electronics.

Synthesis of Al₂O₃ Nanoribbons:

Aluminum oxide (Al₂O₃) nanoribbons were synthesized through a physical vapor transport approach at about 1200° C. To grow Al₂O₃ nanoribbons, aluminum and nanometer-sized Al₂O₃ powders with a molar ratio of about 4:1 were used as the starting materials. The ceramic boat with the mixture was placed at the center of a horizontal tube furnace, and an alumina piece was placed downstream as the deposition substrate. The temperature was raised to the target temperature with a flow of 400 sccm Ar as the carrying gas. The temperature was maintained for 1 h and then naturally cooled to the room temperature.

Dry Transfer of Al₂O₃ Nanoribbons:

The overall process involves physical transfer of Al₂O₃ nanoribbons directly from an Al₂O₃ nanoribbon growth substrate to a graphene substrate via contact printing. Specifically, a graphene device substrate is first firmly attached to a benchtop, and the Al₂O₃ nanoribbon growth substrate is placed upside down on top of the graphene substrate so that the Al₂O₃ nanoribbons are in contact with the graphene. A gentle manual pressure is then applied from the top followed by slightly sliding the growth substrate. The Al₂O₃ nanoribbons are aligned by sheer forces during the sliding process. The sliding process results in direct dry transfer of nanoribbons from the growth substrate to the desired graphene substrate. The sample is then rinsed with isopropanol followed by nitrogen blow-dry, in which the capillary drying process near the Al₂O₃ nanoribbons can contribute toward the Al₂O₃ nanoribbons being firmly attached to the graphene substrate surface.

Characterization of Al₂O₃ Nanoribbons, Device Fabrication and Measurements:

The microstructures and morphologies of the Al₂O₃ nanoribbons were characterized by a JEOL 6700 SEM. The lattice image of the Al₂O₃ nanoribbons was observed by an FEI Titan high-resolution TEM (HRTEM). The thickness was measured using atomic force microscope (AFM, Veeco Dimension 5000). Oxygen plasma (Diener Electronic) was used to selectively etch away the unprotected graphene region and leave graphene ribbons underneath the Al₂O₃ nanoribbon mask protection. The etch time is about 160 s at a power level of about 40 W. The electrical transport properties were measured by a Lakeshore probe station with a customized data acquisition system.

### Example 3

Top-gated graphene transistors were fabricated according to the process shown in FIG. 3. Specifically, Si/HfO₂ core/shell nanowires were synthesized by ALD of HfO₂ on highly-doped silicon nanowires. Using such core/shell nanowires as the top-gates, graphene transistors were fabricated with the HfO₂ shell as an ultra-thin gate dielectric and the silicon nanowire core as the self-integrated gate electrode.

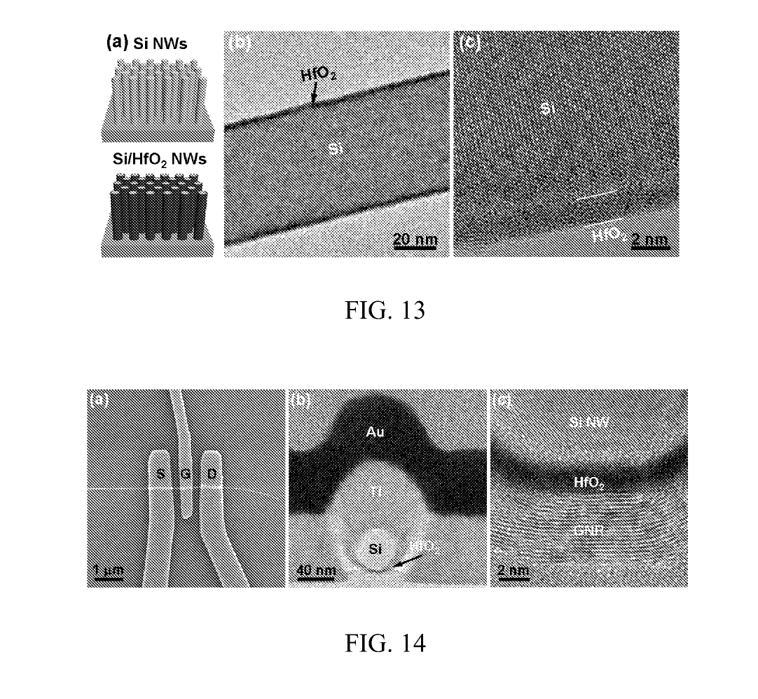

Hafnium oxide is desirable in silicon electronics due to its hardness, high chemical stability and excellent dielectric properties, including a high dielectric constant (˜27) and a wide bandgap (˜5.8 eV). To grow Si/HfO₂ core/shell nanowires, the highly-doped silicon nanowires were first exposed to hydrogen fluoride (HF) vapor to remove the native oxide, and then immediately transferred into ALD chamber to grow HfO₂ shell with controlled thickness at 250° C. by using tetrakis(dimethylamido)hafnium and water as the precursor and oxidant, respectively (FIG. 13a). The relative dielectric constant is determined to be ˜15 based on capacitance-voltage measurement using a planar metal/HfO₂/Si control structure, consistent with previous reports on ALD deposited HfO₂ film. TEM image shows a uniform coating of the amorphous HfO₂ (dark contrast) surrounding the silicon core (light contrast) (FIG. 13b). High resolution TEM image shows the single crystalline silicon core and amorphous HfO₂ shell of higher contrast (FIG. 13c). Additionally, there is a thin layer of SiOₓ transition layer (˜0.5 nm) of lower contrast between the silicon core and HfO₂ shell. The HfO₂ film on Si nanowires is generally quite smooth with few defects, suggesting that the thickness of HfO₂ can be readily controlled with a high degree of uniformity.

FIG. 14a shows a typical top-gated graphene device with Si/HfO₂ core/shell nanowire as the top gate. The gate length is about 500 nm, and the diameter of the nanowire is about 30 nm. Here the Si/HfO₂ core/shell nanowire also functions as a nanoscale etch mask to define a narrow graphene strip (e.g., in the form of a nanoribbon) with a width in the range of about 10 nm-20 nm through aggressive over etch. Cross-section TEM image was used to study the overall gate-stack integration and graphene-HfO₂ interface. The gate stack (SiO₂/graphene/HfO₂/Si/Ti/Au) can be readily observed in the low magnification cross-section TEM image (FIG. 14b). A high resolution TEM image of the graphene-HfO₂ interface shows that the graphene layers are intimately integrated with the Si/HfO₂ nanowire without any noticeable gap or impurities between them (FIG. 14c). A TEM image of the multi-layer graphene device is shown here because it is difficult to visualize the monolayer of graphene nanoribbon under the nanowire due to significant electron-beam damage while conducting TEM studies. Together, these studies demonstrate that the physical assembly approach can effectively integrate an ultra-thin layer of HfO₂ with graphene.

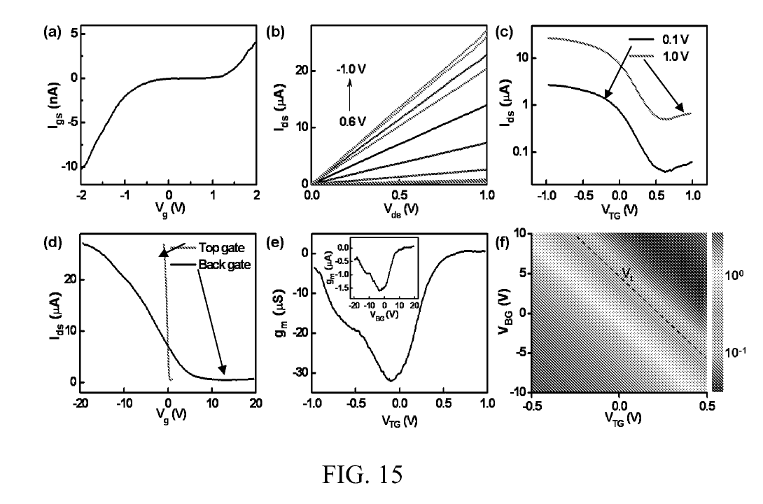

Electrical transport studies of the top-gated device were carried out in ambient condition at room temperature. The gate leakage across the Si/HfO₂/graphene gate stack was first tested before transistor characterization. Of note, the gate tunneling leakage current (I_{gs}) from the Si/HfO₂ core/shell nanowire to the underlying graphene is negligible within the gate voltage range of ±1 V (FIG. 15a). This measurement demonstrates that the 2 nm HfO₂ dielectrics can function as an effective gate insulator for top-gated graphene transistors and afford high gate capacitance desirable for a high transconductance. The drain-source current (I_{ds}) vs. drain-source voltage (V_{ds}) plots at various top gate voltages (V_{TG}) show that the device conductance decreases as the gate potential increases towards positive direction (FIG. 15b), demonstrating that the graphene is p-type doped, which can be attributed to edge oxidation or the physisorbed O₂ from ambient conditions or during the device fabrication process. Figure Hc shows the transfer characteristics drain-source current (I_{ds}) vs. top gate voltage (V_{TG}) curves for the same device at V_{ds}=0.1 V and 1.0 V. The transfer characteristics show the device can be switched on and off with <1 volt of gate swing. The device delivers an on-current of about 27 μA at V_{ds}=1 V and V_{TG}=−1.0 V, and shows a room temperature on/off ratio of ˜70 at V_{ds}=0.1 V, consistent with a graphene with an estimated width of ˜10 nm. To evaluate the top-gated devices versus conventional back-gated devices, the transfer characteristics, I_{ds}−V_{TG}, and back gate voltage (V_{BG}) were measured. Of note, the gate voltage swing to achieve a similar current modulation in the top-gated configuration is more than one order of magnitude smaller than that in the back-gated configuration (FIG. 15d). The transconductance gₘ=dI_{ds}/dV_{TG} can be extracted from the I_{ds}−V_{TG} curve. The maximum gₘ in the top-gated device at V_{ds}=1 V is about 32 μS (FIG. 15e), nearly 19 times of the value obtained in the back-gated configuration (˜1.7 μS) (inset, FIG. 15e).

To further understand the device performance, studies were carried out to determine the gate capacitance, which is not straightforward due to the complex geometry. To this end, a three-dimensional finite element method was used to calculate the capacitance of the device, which yields an electrostatic capacitance (Cₑ) of about 3530 nF/cm² for a 10 nm ribbon under a 30 nm Si/HfO₂ core/shell nanowire with 0.5 nm SiOₓ and 2 nm HfO₂ shell. Of note, this value is already larger than the quantum capacitance (C_{q}˜2000 nF/cm²) in graphene. Taking the top gate capacitance (Cₜₒₚ) as being the series combination of the electrostatic capacitance (Cₑ) and the quantum capacitance (C_{q}), one can obtain Cₜₒₚ=C_{q}Cₑ/(Cₑ+C_{q})=1276 nF/cm². Similarly, one can also calculate the back gate capacitance per area C_{back1}=135 nF/cm² for the portion without the top gate metal electrode covering, and C_{back2}=11.5 nF/cm² for the portion with the top gate metal electrode covering. The differences are due to the screening effect of the top gate metal electrode that can decrease (by ˜1 order of magnitude) the spreading electric field from the back gate. Based on these calculations, a capacitance ratio between the top-gated and the back-gated configuration can be obtained: (C_{Top}·W·L)/(C_{Back1}·W·(L−Lₜₒₚ)+C_{Back2}·W·Lₜₒₚ)=˜18.5, where, W is the graphene width, L is the whole channel length, and Lₜₒₚ is the width of the top gate metal electrode. To experimentally confirm this capacitance ratio, measurements were carried out for the device conductance as a function of both V_{BG} and V_{TG} bias (FIG. 15f). These measurements give threshold voltage (Vₜ) shifts in the top-gated configuration as a function of the applied V_{BG} (FIG. 15f), which can yield the experimental capacitance ratio between the top-gated and back-gated configurations, C_{TG}/C_{BG}≈20, consistent with the finite element calculation described above. This capacitance ratio is also generally consistent with the transconductance ratio between the top- and back-gated configurations. Based on these capacitance analyses, the hole mobility in the graphene device is calculated as μ=(gₘL)(CₜₒₚV_{ds}W)˜880 cm²V⁻¹s⁻¹.

It is interesting to compare the top-gated graphene devices with state-of-the-art silicon MOSFETs. The effective on-current Iₒₙ for a transistor is typically characterized at V_{ds}=V_{g(on-off)}=V_{dd}, where V_{g(on-off)} is the gate voltage swing from off state to on state, and V_{dd} is the power supply voltage. Considering V_{ds}=V_{g(on-off)}=V_{dd}=1V, the Iₒₙ of the graphene device at V_{ds}=1 V and 1 V gate swing from the off state is ˜27 μA. Taking the channel width of the graphene ˜10 nm, the scaled values of Iₒₙ and gₘ of the graphene device are ˜2.7 mA μm⁻¹ and ˜3.2 mS μm⁻¹, exceeding the typical values in sub-100 nm silicon p-MOSFET and n-MOSFET (0.7 mA μm⁻¹ and 0.8 mS μm⁻¹ for p-MOSFET, and 1.66 mA μm⁻¹ and 1.3 mS μm⁻¹ for n-MOSFET) employing high-k dielectrics. This is noteworthy because high transconductance is desirable for transistor performance and voltage gains of transistor-based devices including amplifiers and logic gates.

In conclusion, this example demonstrates a strategy to integrate pristine graphene with ultra-thin, high-k dielectrics, and demonstrates the fabrication of high performance, top-gated graphene transistors with a small dielectric thickness of about 2 nm. This strategy opens a new avenue to integrate high-k dielectrics on graphene with a precise control of dielectric thickness and quality, and can thus open a new avenue to high performance graphene electronics to impact broadly from high speed circuits to flexible electronics.

### Example 4

Top-gated graphene transistors were fabricated according to the process shown in FIG. 4. Specifically, the graphene transistors were fabricated using highly-doped GaN nanowires as top gates, with source and drain electrodes defined through a self-aligned process and a channel length defined by a nanowire diameter or width.

Highly n-doped GaN nanowires were synthesized through a metalorganic chemical vapor deposition (MOCVD) process. SEM studies show that GaN nanowires used typically have a substantially triangular cross section with rounded corners (FIG. 4e). TEM studies show that the GaN nanowires typically have a side width of about 50 nm-100 nm, and lengths on the order of 10 microns. The electron concentration of GaN nanowires is estimated to be n˜2×10¹⁹ cm⁻³ through electrical transport measurements.

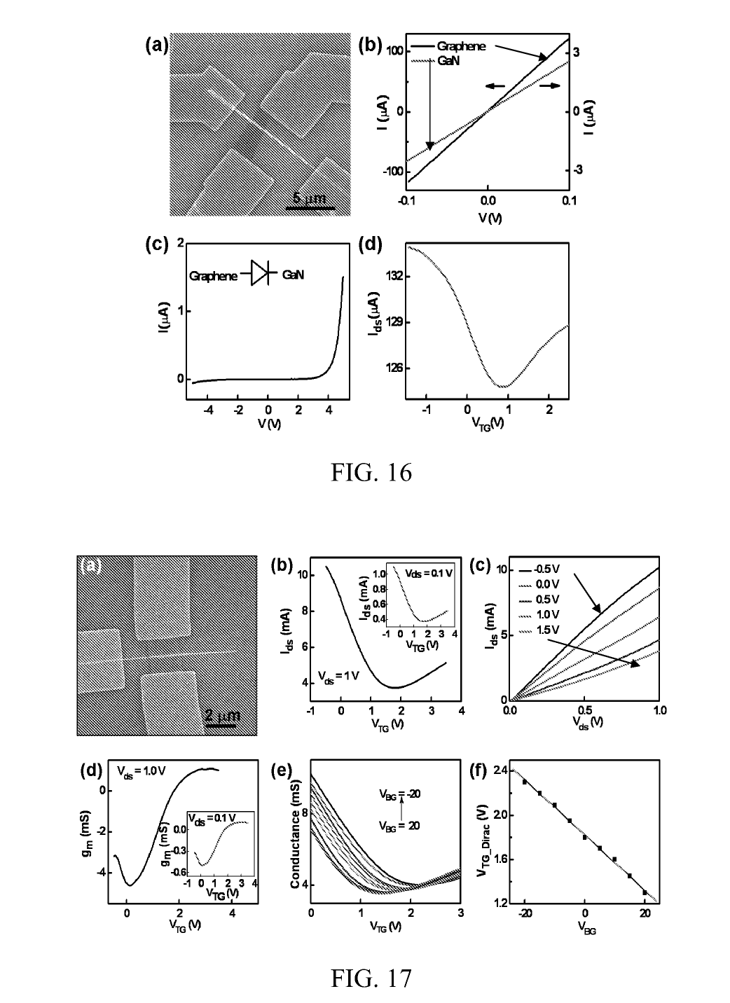

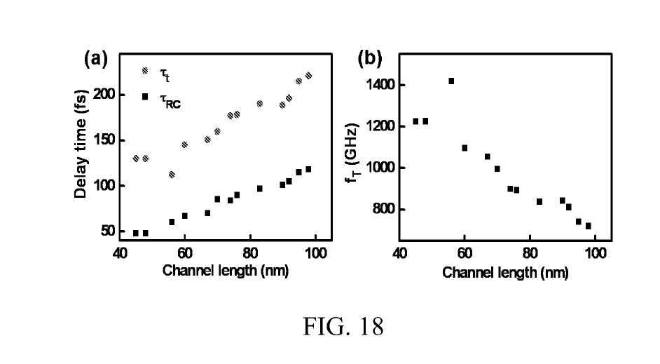

Before the deposition of self-aligned Pt source and drain electrodes (FIG. 16a), graphene/GaN diode characteristics were measured. Electrical measurements on graphene and GaN nanowire itself show linear current-voltage (I−V) characteristics (FIG. 16b). Of note, the current transport across graphene/GaN junction shows clear rectification characteristics with a turn-on voltage around 3.0 V (FIG. 16c), suggesting a significant transport barrier exists between the graphene and the GaN nanowire. The existence of transport barrier between graphene/GaN junction allows using the GaN nanowire as a local top gate for graphene transistors without significant gate leakage. Measurements were carried out for the transfer characteristics, drain-source current I_{ds} versus top gate voltage V_{TG} of this locally gated transistor without self-aligned source-drain electrodes. The I_{ds}−V_{TG} plot shows that the graphene transistor can be modulated by the local nanowire gate, overturning from hole branch to electron branch within −1.5 to 2.5 V range (FIG. 16d), demonstrating the GaN nanowire can function as an effective local gate electrode for graphene transistors. However, the gate modulation is less than 10%, which is smaller than the typical values observed in graphene transistors at room temperature (>50%). It is expected that the contact (or access) resistance dominates the transport in this device because the GaN nanowire local gate modulates a small portion of the entire graphene channel.

To reduce the access resistance and improve the graphene transistor performance, self-aligned source and drain electrodes were deposited using a 10 nm thick Pt metal thin film to ensure precise positioning of the source and drain edges with the gate edge (FIGS. 4d and e). FIG. 17a shows a typical device with 100 nm nanowire gate and 2 μm channel width. With the self-aligned Pt source-drain electrodes, the gate-source leakage remains small compared to the channel current, and therefore would not significantly affect the transistor characteristics. Of note, the I_{ds}−V_{TG} transfer curve recorded for the self-aligned device shows a current modulation of more than 50% (FIG. 17b), comparable to the typical values observed in graphene transistors, suggesting the contact (access) resistance is greatly reduced through the self-alignment process. The hystheresis of I_{ds}−V_{TG} sweep is about 0.2 V in ambient conditions. The I_{ds}−V_{ds} output characteristics at various gate voltages (V_{TG}=−0.5, 0.0, 0.5, 1.0, and 1.5V) show that this device can deliver a significant on-current of about 10 mA at V_{ds}=1 V and V_{TG}=−0.5 V (FIG. 17c). The transconductance gₘ=dI_{ds}/dV_{TG} can be extracted from the I_{ds}−V_{TG} curve (FIG. 17d). A peak transconductance of about 4.6 mS is obtained at V_{ds}=1 V in our device, resulting a scaled transconductance of about 2.3 mS/μm considering the 2 μm channel width of this device. Of note, this scaled transconductance is nearly one order of magnitude better than other reported graphene transistors (Table 2). Additionally, the short channel graphene transistors afford exceptionally high current density. Considering the device dimension (assuming 0.35 nm thickness), a normalized current density of as high as about 2.3×10⁹ A/cm² is achieved at V_{ds}=1.8 V before the device breaks down, which exceeds values reported in other graphene devices, and is comparable to that of metallic single-walled nanotube (or more than 3 orders of magnitude greater than that in typical metals such as copper).

To determine the gate capacitance, the device conductance was measured as a function of both V_{TG} bias and back gate voltage (V_{BG}) (FIG. 17e). From these measurements, Dirac point shifts in the top-gated configuration can be determined as a function of the applied V_{BG} (FIG. 17f), which gives the ratio between top gate and back gate capacitances, C_{T}/C_{BG}≈42. Using the back gate capacitance value of C_{BG}=11.5 nF/cm², the top gate capacitance is estimated to be C_{TG}=483 nF/cm.

To precisely determine the graphene channel length, SEM was used to measure the gap width (channel length) between the Pt source and drain electrodes. The graphene channel can be exposed and observed with SEM when the nanowire gate is removed by a brief sonication process. The channel lengths of the resulting graphene transistors are mainly determined by nanowire side width so that variable graphene channel lengths in the sub-100 nm regime can be readily obtained using different sized nanowires. This approach is scalable and can be extended for the fabrication of sub-10 nm channel length graphene transistors by employing smaller nanowires.

One benchmark of transistor performance is the cut-off frequency. In general, the cut-off frequency of a transistor can be affected by two timescales: resistance-capacitance (RC) delay time (τ_{RC}), and transit time across the channel length (τₜ). The cut-off frequency is described as below:

$${τ}_{RC} = RC , \\ {τ}_{t} = \frac{C}{{g}_{m}} , \\ {f}_{T} = \frac{1}{2 πτ} , τ = max ( {τ}_{RC} , {τ}_{t} ) ,$$

where C is the gate capacitance, R is the resistance of conducting channel, and gₘ is maximum or peak transconductance. For a given device, R typically does not change with V_{ds} before current saturation at high electrical field, while gₘ typically increases with increasing V_{ds} before current saturation. For the device shown in Figure J, the calculated τ_{RC} is about 102 fs, and the calculated τₜ is about 189 fs at V_{ds}=1V. Therefore, the cut-off frequency of this graphene device is dominated by the transit time τₜ at V_{ds}=1V, with the expected f_{T} for this 90 nm channel long (GaN nanowire side width 100 nm) graphene transistor calculated to be about 840 GHz, which is about 8 times faster than that of silicon MOSFET of comparable size (e.g., about 100 GHz for a 90 nm Si-MOSFET), about two times higher than that of similar-length carbon nanotube devices, and faster than other reports of graphene devices shown in Table 2.

TABLE 2

| Top-gate dielectric deposition | Mobility | gₘ@V_{ds} = 1 V | C_{TG} | Length | Transit time |
|---|---|---|---|---|---|
| approach | (cm²/Vs) | (mS/μm) | (nf/cm²) | (nm) | @V_{ds} = 1 V (ps) |
| ALD Al₂O₃ with NO₂ functionalization⁷ | 400 | 0.025 | 555 | 360 | 80 |
| ALD HfO₂ directly on graphene²⁵ | 1200 | 0.094 | 552 | 1000 | 58.7 |
| ALD Al₂O₃ with polymer buffer layer²⁶ | 7400 | 0.280 | 184 | 1100 | 7.22 |
| ALD Al₂O₃ with Al buffer layer²³ | 2700 | 0.275 | 400 | 350 | 5.09 |
| ALD HfO₂ with polymer buffer layer²⁴ | ~1520 | 0.8 | 1600 | 240 | 4 |
| Self-aligned nanowire top-gate | ~20000¹⁴ | 2.3 | 483 | 90 | 0.189 |

Table 2 sets forth various parameters of top-gated graphene transistors at V_{ds}=1V. The transconductance gₘ values are scaled to V_{ds}=1V assuming a linear I_{ds}−V_{ds} relationship. The transit time is calculated using τₜ=gₘ/C_{TG}. Since the channel length of the sub-100 nm device is less than the typical mean free path in graphene (˜1 micron), it is not straightforward to determine the carrier mobility values using a diffusive transport model. The mobility value cited for the device with self-aligned nanowire gate is from previous studies on a longer device using physically assembled oxide nanoribbons as the top gate dielectrics, in which a carrier mobility exceeding 20,000 cm²/Vs was achieved in top-gated graphene transistors.

A summary of the τ_{RC} and τₜ for the self-aligned graphene transistors of variable channel lengths is shown in Figure Ka, and the expected cut-off frequency f_{T} is shown Figure Jb. A cut-off frequency f_{T} exceeding 1 terahertz can be reached in sub-70 nm channel length devices. Future studies using lower resistance nanowire gate electrode can reduce the gate delay, and facilitate graphene transistor operation in the terahertz regime.

In summary, this example describes a self-aligned process to fabricate sub-100 nm graphene transistors with a nanowire gate. The device layout ensures that the edges of the source, drain, and gate electrodes are automatically and precisely positioned such that no overlapping or significant gaps exist between these electrodes and thus can simultaneously minimize the access resistance and parasitic capacitance. The fabrication approach allows integration of a top gate electrode without introducing damage into pristine graphene lattice. In such manner, the high electronic performance of graphene can be retained to provide graphene transistors with several advantages, including unprecedented drive current, transconductance, and intrinsic delay time in graphene transistors. These studies thus open an avenue to high performance graphene transistors that can lead to graphene-based, high-speed, high-frequency electronics.

### Example 5

Top-gated graphene transistors were fabricated according to the process shown in FIG. 5. Specifically, the graphene transistors were fabricated using Co₂Si/Al₂O₃ core/shell nanowires as the self-aligned top gate, which were transferred onto graphene through a physical assembly process at room temperature. The source and drain electrodes were defined through a self-alignment process to ensure precise alignment with the nanowire gates.

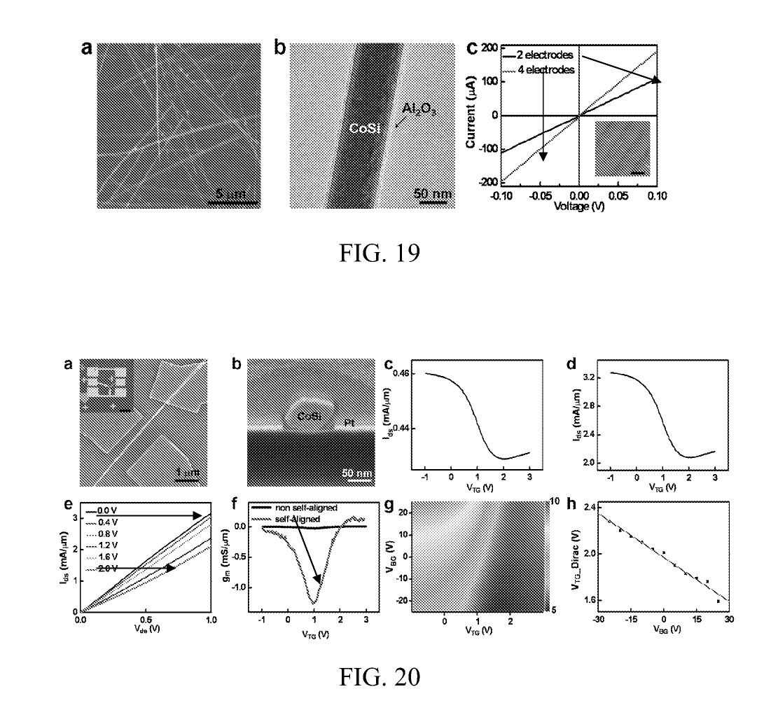

The Co₂Si nanowires were synthesized through a chemical vapor deposition (CVD) process with the diameters typically in the range of about 100 nm-300 nm and the lengths of about 10 μm (FIG. 19a). The composition of Co₂Si was characterized by energy-dispersive C-ray spectroscopy. The Co₂Si/Al₂O₃ core/shell nanowires were grown through ALD of Al₂O₃ shell on the Co₂Si nanowires with controlled thickness. The relative dielectric constant of ALD-deposited Al₂O₃ is determined to be ˜7.5 based on capacitance-voltage measurement using a planar metal/Al₂O₃/Si control structure. A TEM image shows an uniform coating of the amorphous Al₂O₃ (light contrast) surrounding the single-crystal Co₂Si core (dark contrast) (FIG. 19b). High resolution TEM image shows the single crystalline Co₂Si core with amorphous Al₂O₃ shell of lighter contrast. The electrical measurement of a Co₂Si nanowire shows linear current-voltage (I−V) characteristics (FIG. 19c) with the resistance of a 180 nm diameter and 3 micron long Co₂Si nanowire close to about 527 ohm, and an estimated resistivity of about 437 μΩ·cm. The low resistance is particularly desirable for the Co₂Si nanowire to function as an effective gate electrode for high frequency transistors without significant gate delay.

FIG. 20a shows a SEM image of a self-aligned graphene transistor and an optical microscope image of the overall device layout (inset, FIG. 20a). The cross-sectional SEM image of the device shows the self-aligned Pt thin film source and drain electrodes are well separated by the nanowire gate and precisely positioned next to the nanowire gate (FIG. 20b), demonstrating that the self-alignment process can be used to effectively integrate graphene with a nanowire gate and precisely positioned source-drain electrodes.

Prior to the formation of the self-aligned Pt source and drain electrodes, measurements were carried out for the transfer characteristics, drain-source current (I_{ds}) versus top gate voltage (V_{TG}) applied by the local nanowire gate. The I_{ds}−V_{TG} plot shows that the graphene transistor can be modulated by the local nanowire gate, overturning from the hole branch to electron branch within −1 V to 3 V range (FIG. 20c), demonstrating the Co₂Si/Al₂O₃ core/shell nanowire can indeed function as an effective local gate electrode for the graphene transistors. However, the gate modulation is less than 10%, smaller than the typical values observed in graphene transistors at room temperature (around 50%). This difference can be attributed to the access resistance arising from the relatively small gated area compared to the entire graphene channel.

The formation of the self-aligned source and drain electrodes allows precise positioning of the source-drain edges with the gate edges, which substantially reduces the access resistance and improves the graphene transistor performance. Before transistor characterization of the self-aligned device, initial testing was carried out for the gate leakage across the Co₂Si/Al₂O₃/graphene gate stack. The gate tunneling leakage current (I_{gs}) from the Co₂Si/Al₂O₃ core/shell nanowire to the underlying graphene is negligible within the gate voltage range of ±4 V range. This measurement demonstrates that the 5 nm Al₂O₃ dielectrics can function as an effective gate insulator for top-gated graphene transistors and afford high gate capacitance to achieve high transconductance. Of note, the I_{ds}−V_{TG} transfer curve recorded for a self-aligned device shows a current modulation of about 40% (FIG. 20d), comparable to the typical values observed in graphene transistors, suggesting the access resistance in this ultra-short channel device is largely removed through the self-alignment process. The hysteresis of I_{ds}−V_{TG} is about 0.02 V under ambient conditions, demonstrating the relative clean nature of the graphene-dielectric interface. The I_{ds}−V_{ds} output characteristics at various gate voltages (V_{TG}=0.0, 0.4, 0.8, 1.2, 1.6, and 2.0 V) show that this device can deliver a significant scaled on-current of 3.2 mA/μm at V_{ds}=1 V (FIG. 20e). The transconductance gₘ=dI_{ds}/dV_{TG} can be extracted from the I_{ds}−V_{TG} curve (FIG. 20f). A peak scaled transconductance of 0.02 mS/μm is obtained at V_{ds}=1 V for the device prior to the deposition of the self-aligned source and drain electrodes. Significantly, with the self-aligned source drain electrodes, the peak scaled transconductance of 1.25 mS/μm is obtained at V_{ds}=1 V, which is more than 60 times improvement over the non-self-aligned device. This study demonstrates that the self-alignment process can ensure high transistor performance in short channel devices.

To characterize the gate capacitance, measurements were carried out for the device conductance as a function of both V_{TG} and back gate bias (V_{BG}) (FIG. 20g). From these measurements, Dirac point shifts in the top-gated configuration was obtained as a function of the applied V_{BG} (FIG. 20h), which gives the ratio between top gate and back gate capacitances, C_{TG}/C_{BG}≈38. Using the back gate capacitance value of C_{BG}=11.5 nF/cm², the top gate capacitance is estimated to be C_{TG}=437 nF/cm², which is consistent with the results obtained from the finite element calculations, C_{TG}=˜394 nF/cm².

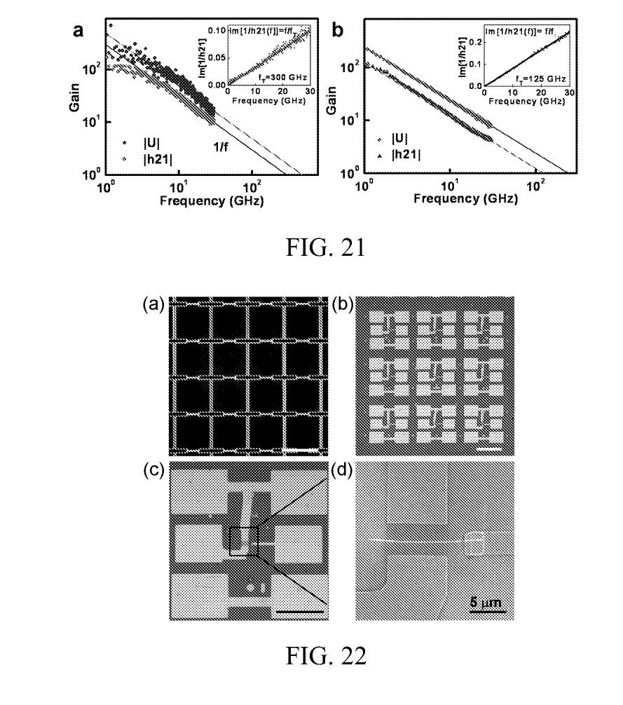

One benchmark of transistor performance is the cut-off frequency f_{T}. To assess the RF characteristics of self-aligned transistors, on-chip microwave measurements were carried out in the range of 50 MHz to 30 GHz using an Agilent 8722ES network analyzer. The measured S-parameters were de-embedded using specific “short”, “open,” and “through” structures with the identical layouts, excluding the graphene channel, to remove the effects of parasitic capacitance and resistance associated with the pads and connections, and the “load” calibration was carried out with a standard calibration pad. FIG. 21a shows the current gain |h21| derived from the measured S-parameters at V_{TG}=1 V and a drain bias V_{ds}=1 V. Displayed is the 1/f frequency dependence expected for an ideal FET, yielding a f_{T} of about 300 GHz. The f_{T} data was verified through Gummel's approach (inset, FIG. 21a), in which the extracted f_{T} is identical to the aforementioned value. Gummel's approach was originally developed for bipolar transistors, but it also applies to FETs. This value is also consistent with the projected value (316 GHz) using the relation f_{T}=gₘ/(2πC) established for conventional FETs. The speed of this self-aligned graphene device is about 5 times faster than that of silicon MOSFET of comparable size (e.g., about 60 GHz for a 150 nm Si-MOSFET), and is faster than that other reported graphene devices. In addition to the current gain, another figure-of-merit for microwave performance is the maximum oscillation frequency fₘₐₓ, which corresponds to the highest frequency with non-vanishing power gain. The fₘₐₓ of the graphene transistors was measured to be about 500 GHz, extracted from Mason's unilateral gain. FIG. 21b further shows the results obtained from a self-aligned graphene transistor with a 210 nm nanowire gate, displaying a f_{T} and fₘₐₓ of 125 GHz and 240 GHz, respectively.

In summary, this example describes a self-aligned process to fabricate graphene transistors with a nanowire gate. The device layout ensures that the edges of the source, drain, and gate electrodes are automatically and precisely positioned such that no overlapping or significant gaps exist between these electrodes and thus can simultaneously minimize the access resistance and parasitic capacitance. The fabrication approach allows integration of a top gate electrode without introducing damage into pristine graphene lattice. In such manner, the high electronic performance of graphene can be retained to provide graphene transistors with several advantages, including unprecedented drive current, transconductance, f_{T}, and fₘₐₓ. The high f_{T} and fₘₐₓ demonstrates the use of graphene-based, high-speed, high-frequency electronics for applications such as millimeter- and sub-millimeter-wave power amplifiers. With further optimization of graphene growth over large area and nanowire assembly process to precisely control their physical dimension and spatial location, large arrays of self-aligned graphene transistors or circuits can be implemented. This approach can thus open an avenue to high performance graphene electronics to impact broadly from high frequency high speed circuits to flexible electronics.

Synthesis and Characterization:

Co₂Si nanowires were synthesized through a chemical vapor deposition process at about 850° C. To grow Co₂Si nanowires, CoCl₂ powder was used as the starting material. A ceramic boat with the CoCl₂ powder was placed upstream of a horizontal tube furnace, a silicon substrate in another ceramic boat was placed at the center as the silicon source, and a SiO₂/Si substrate was placed on the silicon substrate as the deposition substrate. The temperature was raised to the target temperature with a flow of 200 sccm Ar as the protecting medium and carrying gas. The temperature was maintained for about 30 min and then naturally cooled to the room temperature to obtain Co₂Si nanowires. To grow Co₂Si/Al₂O₃ core/shell nanowires, the Co₂Si nanowires were immediately transferred into an ALD chamber to grow Al₂O₃ shell with controlled thickness at about 250° C. using trimethylaluminum and water as the precursor and oxidant, respectively. The microstructures and morphologies of the nanostructures were characterized by a JEOL 6700 SEM. The TEM image of the Co₂Si nanowires was obtained with an FEI Titan high-resolution TEM (HRTEM).

Contact Printing of Nanowires on Graphene:

The overall process involves physical transfer of nanowires directly from a Co₂Si nanowire growth substrate to a graphene substrate via contact printing. Specifically, mechanically peeled graphene flakes on silicon substrate were used as the starting materials. The graphene device substrate is first firmly attached to a benchtop, and the Co₂Si nanowire growth substrate is placed upside down on top of the graphene substrate such that the Co₂Si nanowires are in contact with the graphene. A gentle manual pressure is then applied from the top followed by slightly sliding of the growth substrate. The Co₂Si nanowires are well-aligned by shear forces during the sliding process. The sliding process results in the direct and dry transfer of Co₂Si nanowires from the growth substrate to the graphene substrate. The sample is then rinsed with acetone followed by nitrogen blow-dry, in which the capillary drying process near the nanowire-graphene interface can contribute towards the Co₂Si nanowires being firmly attached to graphene surface.

Device Measurement:

The DC electrical transport measurements were conducted with a Lakeshore Cryogenic probe station (Model CRX-4K) and a computer-controlled analog-to-digital converter (National Instruments model 6030E). The DC measurements were conducted under light illumination to avoid deep depletion in the highly resistive silicon substrate. The on-chip microwave measurements were carried out in the range of 50 MHz to 30 GHz using an Agilent 8722ES network analyzer. The measured S-parameters were de-embedded using specific “short,” “open,” and “through” structures with identical layouts, excluding the graphene channel, to remove the effects of the parasitic capacitance and resistance associated with the pads and connections, and the “load” calibration was done with a standard calibration pad. To achieve high fidelity in the de-embedding process, the layouts of these “open,” “short,” and “through” structures are substantially identical with that of the active device except the graphene channel.

### Example 6

Top-gated graphene transistors were fabricated according to the process shown in FIG. 6. Specifically, the graphene transistors were fabricated on a glass substrate with chemical vapor deposition (CVD) grown graphene and dielectrophoretic assembled nanowire top gated arrays.

The quality of the graphene is characterized using micro-Raman spectroscopy, suggesting a continuous single layer graphene with few defects. Electrical transport studies of standard back-gated devices on silicon/silicon oxide substrate show that the carrier mobility values of 1000-2000 cm²/V·s are typically observed, demonstrating a good quality of the CVD-grown graphene. FIG. 22a shows 20 pairs of finger electrode array on the substrate, with each pair of electrodes bridged by a single nanowire. FIG. 22b shows an array of nine self-aligned graphene transistors, and FIG. 22c and FIG. 22d show zoomed-in picture of an individual self-aligned graphene transistor.

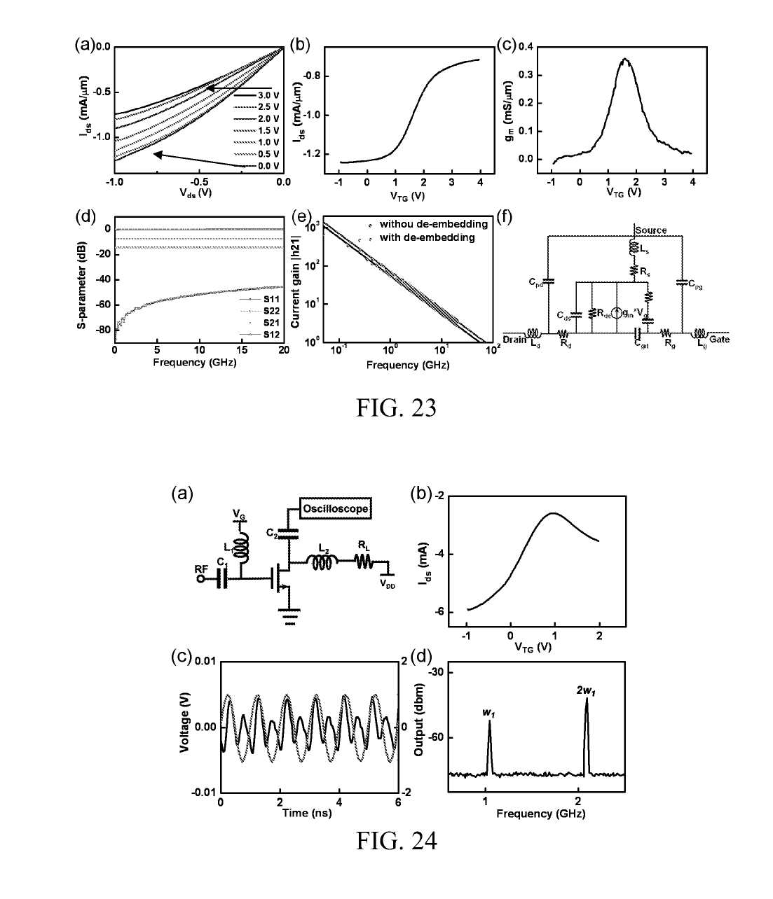

FIG. 23 shows electrical performances of a typical graphene transistor with the gate nanowire diameter (channel length) of about 170 nm. The I_{ds}−V_{ds} output characteristics at various gate voltages show that this device can deliver a significant on-current of about 1.26 mA/μm at V_{ds}=−1 V and V_{TG}=0.0 V (FIG. 23a). Interestingly, a slight current saturation is observed in this short channel device, which becomes more apparent when the channel length further increases to 240 nm. The current saturation is desirable for power gain performance in RF graphene transistors. The observed current saturation can be attributed to gate induced shifting of Dirac point due to the large gate-drain capacitance coupling. The transfer characteristics (FIG. 23b) show that the full current modulation can be achieved with a relatively small gate swing of about 1 V, from which the transconductance gₘ=dI_{ds}/dV_{TG} can be derived. Of note, a peak transconductance of about 0.36 mS/μm can be obtained at V_{ds}=−1 V (V_{TG}=1.5 V) (FIG. 23c). The above discussions demonstrate that the self-aligned nanowire gate can allow high DC performance in CVD graphene transistors.

One benchmark of the transistor RF performance is the cut-off frequency f_{T}. To assess the RF characteristics of the self-aligned transistors, on-chip microwave measurements were carried out in the range of 50 MHz to 20 GHz using an Agilent 8722ES network analyzer. To accurately determine the intrinsic f_{T} values generally involves careful de-embedding procedures using the exact pad layout as “open” and “short” test structures. The scattering S-parameters that relate the AC currents and voltages between the drain and the gate of the transistor were first measured (FIG. 23d). The de-embedded S parameters constitute a complete set of coefficients to describe intrinsic input and output behavior of the graphene device and can be used to derive other characteristic parameters such as gain. FIG. 23e shows the small signal current gain |h21| derived from the measured S-parameters at V_{TG}=1.6 V and V_{ds}=−1 V. The curve displays the typical 1/f frequency dependence expected for an ideal FET. The linear extrapolation yields a f_{T} value of about 72 GHz. To further confirm the accuracy of the de-embedding process, S-parameter measurements were used to extract all device component values based on the equivalent circuit (FIG. 23f). Of note, the device component values (including transconductance, parasitic capacitance, gate capacitance, and so forth) derived from the RF measurements are consistent with those obtained from the DC measurements or electrostatic simulations (Table 3). The observed f_{T} value of about 72 GHz can be affected by the quality of the CVD graphene, and can be further improved upon improving the quality of the CVD graphene.

TABLE 3
The component parameter values for the device shown in FIG. 23.

| C_{pg} | R_{g} | R_{ds} | gₘₒ | τ | Rᵢ | C_{ds} | C_{gs} | C_{gd} | L_{d} | L_{g} | Lₛ | Rₛ | R_{d} |
|---|---|---|---|---|---|---|---|---|---|---|---|---|---|
| (fF) | (ohm) | (ohm) | (mS) | (ps) | (ohm) | (fF) | (fF) | (fF) | (pH) | (pH) | (pH) | (ohm) | (ohm) |
| 1.9 | 390 | 124 | 2.7 | 0.6 | 235 | 0.5 | 5.5 | 0.6 | 54 | 130 | 11 | 4.7 | 11.6 |

High-speed graphene transistors reported to date typically have a rather low extrinsic cut-off frequency around 10 GHz or less, although these transistors can have higher intrinsic f_{T}. This difference between intrinsic and extrinsic f_{T} can be primarily attributed to the large ratio between parasitic pad capacitance and gate capacitance. Previous devices are typically fabricated either on highly resistive silicon or semi-insulating silicon carbide substrate with large parasitic capacitance, which can limit the achievable extrinsic f_{T}. Of note, the component value analysis of the current device (Table 3) reveals that the ratio between parasitic capacitance and gate capacitance is rather small, due to a greatly reduced parasitic capacitance with the use of insulating quartz substrate. The small parasitic/gate capacitance ratio achieved in the current device suggests that high extrinsic f_{T} value can be achievable. Indeed, measurement without the de-embedding procedures shows an extrinsic f_{T} value of 55 GHz.

The achievement of such high extrinsic f_{T} can allow the implementation of graphene transistor based RF circuits that can operate in the gigahertz regime. To this end, graphene transistors were configured into RF frequency doublers and mixers. The ambipolar transport properties of graphene transistors can allow the development of a new generation of nonlinear electronics for RF signal-doubling applications. FIG. 24a and FIG. 24b show schematic circuit diagram of the graphene transistor based frequency doubler and the substantially symmetrical transfer characteristics of a graphene transistor around the Dirac point. Of note, with the excellent extrinsic f_{T}, the frequency doubler configured using the self-aligned graphene transistors shows a clear doubling function with the input signal frequency at about 1.05 GHz (FIG. 24c). Most of the output power is concentrated at the doubling frequency of about 2.1 GHz. Spectrum analysis shows that the frequency doubler device exhibits a high spectral purity in the output RF signal, with about 90% of the output RF energy at the doubling frequency (about 2.1 GHz) (FIG. 24d). This study demonstrates a single graphene transistor based frequency doubler that can operate in the gigahertz regime with high output spectral purity.

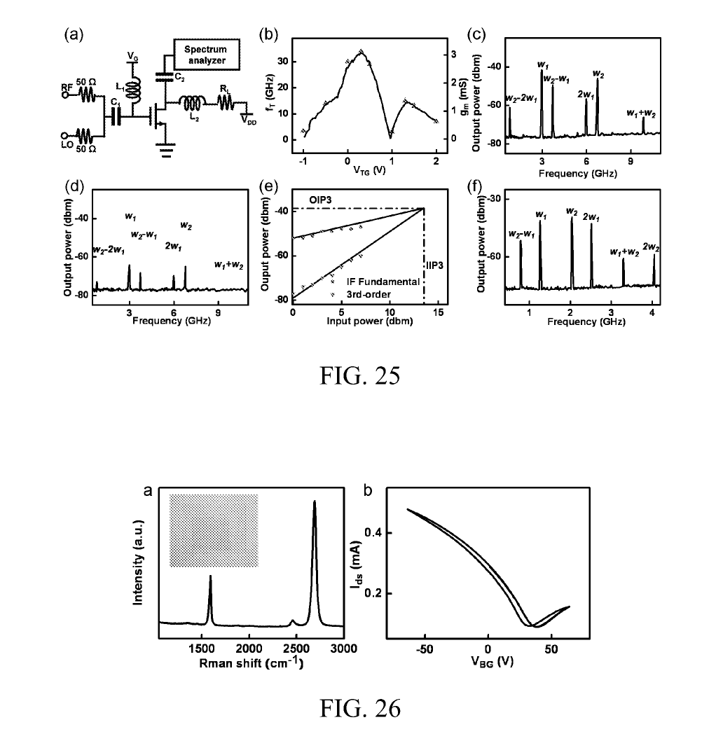

Studies were also carried out on a single graphene transistor based RF mixer (FIG. 25a) and its two-tone measurements. The two tone signals with adjacent frequencies are applied to the gate through a power combiner to manipulate the transistor channel resistance. In general, the DC transconductance gₘ and f_{T} of a graphene transistor depends on the exact gate voltage. For the device shown in FIG. 25b, as the gate voltage is varied, f_{T} follows the amplitude of gₘ, with a maximum f_{T} of ˜34 GHz corresponding to the peak gₘ of 3.0 mS at V_{TG}=0.3 V. To explore the operation frequency limits of the graphene transistor based mixer, it is desirable to properly gate and bias the graphene transistors with optimized gₘ and f_{T}. FIG. 25c shows the output spectrum of the RF mixer with the RF input f_{RF}=6.72 GHz and local oscillator f_{LO}=2.98 GHz when the device is operating at V_{ds}=−1.0 V and V_{TG}=0.3 V with a maximum extrinsic f_{T}=34 GHz. The RF mixing function is seen at intermediate frequency (IF) f_{IF}=f_{RF}=f_{LO}=3.74 GHz and f_{IF}=f_{RF}+f_{LO}=9.70 GHz. On the other hand, upon biasing the device at smaller V_{ds}=0.2 V at the same gate voltage of 0.3V (extrinsic f_{T}˜7 GHz), the output spectrum shows that power at all frequencies are greatly reduced, and f_{IF}=f_{RF}+f_{LO}=9.70 GHz disappeared (FIG. 25d). Similarly, biasing or gating at a different voltage with smaller gₘ can generally result in a degradation of the output power. These studies demonstrate the reasons to improve the gₘ and extrinsic f_{T} for optimized power output at high frequencies.

The third-order intercept point (IP3) in a mixer is typically defined by the extrapolated intersection of the primary IF response with the two-tone third-order intermodulation IF product generated by 2f₁±f₂ or 2f₂±f₁. The IP3 is a benchmark parameter to characterize the linearity of the RF mixer and is the most commonly used figure of merit to describe the intermodulation distortion of an RF mixer. FIG. 25e shows the characterization of the third-order intermodulation product using two-tone measurements. The output power at IF and third-order intermodulation frequency (0.76 GHz) follows the theoretical 10- and 30-dB/dec dependences, respectively. A third-order intermodulation intercept (IIP3) of about 13.5 dbm is achieved, comparable to 0.18 μm COMS mixers and previously reported graphene mixer (operating at lower frequencies).

It is expected that the symmetrical transfer characteristics can suppress the harmful odd-order intermodulation distortions. In order to take advantage of this point, it is desirable to gate the device near the Dirac point. FIG. 25f shows the dependence of the signal power at intermediate frequency (IF) f_{IF}=f_{RF}−f_{LO}=0.75 GHz with the RF input f_{RF}=1.26 GHz and f_{LO}=2.01 GHz when the transistor operates near the Dirac point with V_{ds}=−1.0 V and V_{TG}=1.0 V. Of note, the output spectrum shows that there is no third-order intermodulation frequency when the transistor is gated near the Dirac point. In contrast, upon changing the V_{TG} away from the Dirac point (e.g., to the maximum transconductance point, V_{TG}=0.3 V), the third-order intermodulation frequency can be observed (FIG. 25c,d). These studies demonstrate that the odd-order intermodulations can be significantly suppressed in graphene transistor based mixers operating around Dirac point due to the ambipolar symmetrical transfer characteristics.

In summary, this example demonstrates a scalable process to fabricate self-aligned CVD graphene transistor arrays on glass with nanowire gates by dielectrophoretic assembly process. With the reduction of parasitic capacitance on insulating substrate, the graphene transistors exhibit a high extrinsic cut-off frequency (>50 GHz), which therefore readily allows the implementation of graphene transistor based frequency doubling and mixing circuits that can operate in the gigahertz regime. These studies open a pathway to scalable fabrication of high speed, self-aligned graphene transistors and functional circuits, such as graphene based RF circuits.

Synthesis and Characterization:

Co₂Si nanowires were synthesized through a chemical vapor deposition process at about 850° C. To grow Co₂Si nanowires, CoCl₂ powder was used as the starting material. A ceramic boat with the CoCl₂ powder was placed upstream of a horizontal tube furnace, a silicon substrate in another ceramic boat was placed at the center as the silicon source, and a SiO₂/Si substrate was placed on the silicon substrate as the deposition substrate. The temperature was raised to the target temperature with a flow of 200 sccm Ar as the protecting medium and carrying gas. The temperature was maintained for about 30 min and then naturally cooled to the room temperature to obtain Co₂Si nanowires. To grow Co₂Si/Al₂O₃ core/shell nanowires, the Co₂Si nanowires were immediately transferred into an ALD chamber to grow Al₂O₃ shell with controlled thickness at about 250° C. using trimethylaluminum and water as the precursor and oxidant, respectively.

The graphene was grown by chemical vapor deposition on copper foil at about 1050° C. with methane as the carbon-containing precursor. At first, Cu foils (about 25 μm thick, 99.8%, Alfa Aesar) were loaded into a 1 inch quartz tube inside a horizontal furnace of a commercial CVD system. The furnace is then allowed to heat up to about 1080° C. with H₂/Ar flow (25 sccm/475 sccm) to anneal the Cu foil for about 90 minutes. After annealing, the temperature is dropped to about 1050° C. in about 10 minutes. The graphene growth was initiated by feeding methane (500 ppm methane in Ar, 35 sccm) balanced with the H₂/Ar (25 sccm/440 sccm). After growth, the graphene was transferred onto silicon/silicon oxide or glass substrate for characterization and device fabrication. Initially, the graphene was grown on both sides of the copper foils. To transfer the graphene, a layer of PMMA film was spin coated onto one side of the graphene/Cu foil, and the other side was cleaned with O₂ plasma. The copper is then etched away using copper etchant by floating the foil on the surface of the etchant bath. The PMMA/graphene film is washed with HCl/H₂O (1:10) and DI water several times, and transferred onto silicon/silicon oxide or glass substrate.

Device Fabrication:

Dielectrophoretic nanowire assembly is carried out in a fluid cell in a four-step process: loading, flushing, locking, and drying. First, a medium voltage (5V, 100 Hz) was set for initial dielectrophoretic assembly. As the nanowires flowed across the surface, the nanowires became trapped above electrode pairs. Once all the electrodes were filled, excess nanowires were removed. Flowing nanowire-free solvent mixture through the cell flushed excess nanowires from the channel and channel top surface. Once the excess nanowires were removed from the cell, the fluid flow stopped, and the applied voltage increased to 7 V. At this voltage, the nanowires adhered irreversibly to the electrodes by means of van der Waals forces (locking). The adhesion of the nanowires onto the surface was further improved by flowing pure isopropanol (IPA) through the cell to remove water. The IPA was then drained, and the cell purged with N₂ to dry the substrate. In this way, a single Co₂Si/Al₂O₃ core/shell nanowire was aligned on top of each graphene block, followed by e-beam lithography, buffered oxide etching to remove the Al₂O₃ shell and expose the Co₂Si core, and metallization (Ti/Au, about 70/50 nm) process to define the source, drain and gate electrodes. A thin layer of Pt metal (about 10 nm) was then deposited on top of the graphene across the Co₂Si/Al₂O₃ core/shell nanowire, in which the Co₂Si/Al₂O₃ core/shell nanowire separates the Pt thin film into two isolated regions that form the self-aligned source and drain electrodes precisely positioned in close proximity to the nanowire gate.

Device Measurement:

The DC electrical transport measurements were conducted with a Lakeshore probe station (Model CRX-4K) under ambient conditions and a computer-controlled analogue-to-digital converter (National Instruments model 6030E). The on-chip microwave measurements were carried out in the range of 50 MHz to 20 GHz using Cascade RF probes and an Agilent 8722ES network analyzer. The measured S-parameters were de-embedded using specific “short” and “open” structures with identical layouts, excluding the graphene channel, to remove the effects of the parasitic capacitance and resistance associated with the pads and connections. The “through” calibration was done with exact pad layout with gate shorted to drain, and the “load” calibration was done with standard calibration pad. To achieve high fidelity in the de-embedding process, the layouts of these “open,” “short,” and “through” structures are substantially identical with that of the active device except the graphene channel. The two-tone intermodulation measurement was conducted with HP 8592A spectrum analyzer, HP 83711B, and Fluke signal generator.

Characterization of CVD Graphene:

FIG. 26(a) shows the Raman spectrum of CVD graphene, and the inset shows a photograph of a piece of CVD graphene on glass. FIG. 26(b) shows the transfer characteristics of a typical back-gated CVD graphene transistor on silicon/silicon oxide, with which the carrier mobility of graphene was derived (about 1000-2000 cm²/V·s).

### Example 7

Top-gated graphene transistors were fabricated according to the process shown in FIG. 7. Specifically, arrays of gate stacks were first patterned on a sacrificial substrate, and then transferred onto a substrate with graphene on top. A self-aligned process, facilitated by the structure of the gate stack, was used to precisely position the source and drain electrodes with reduced access resistance or parasitic capacitance.

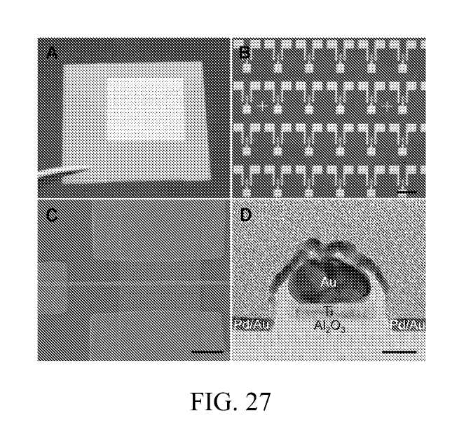

As shown in FIG. 27, arrays of self-aligned graphene transistors with uniform device geometry and spacing are demonstrated on glass (FIG. 27A) and 300 nm Si/SiO₂ substrate (FIG. 27B). FIG. 27C shows a SEM image of the top view of an individual self-aligned graphene transistor. The cross-sectional TEM image shows that the self-aligned source and drain electrodes are well separated and precisely positioned next to the gate spacer dielectric (FIG. 27D). Since the device performance is determined by the structure of the individual gate stack and the self-aligned source and drain electrodes, the relative large gap between external source-drain lead electrodes may not affect the device performance, rather making it more tolerant to any transfer induced misalignment and distortion of the gate stacks arrangement.

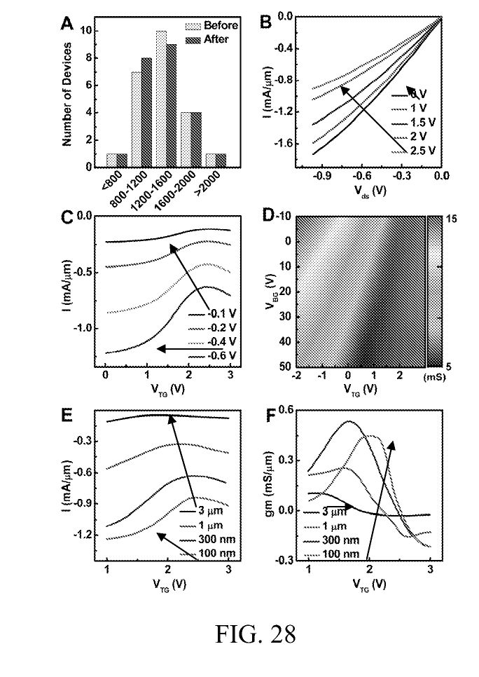

The conventional dielectric integration approach can often introduce significant defects into graphene lattice and degrade its electronic performance (e.g., carrier mobility). To investigate the impact of the transferring method on graphene carrier mobility, studies were carried out for the electrical performance and carrier mobility distribution of more than 20 graphene transistors (in the back-gated configuration) before and after dielectric integration. Here, the CVD grown graphene is patterned by photolithography with a channel length ˜8 μm and a channel width ˜8 μm. The effective mobility values are extracted from the drain-source current (I) versus the back-gated voltage (V_{BG}) (I_{ds}−V_{BG}) curves. Of note, a histogram of the mobility value shows that the CVD grown graphene exhibits a similar mobility distribution in the range of about 1000-2000 cm²/V·s before and after the transfer dielectric integration process (FIG. 28A). These studies demonstrate that the transfer gate approach does not lead to a noticeable degradation of the electronic performance of the graphene.

FIG. 28B through FIG. 28F depict the room-temperature electrical transport characteristics of the self-aligned graphene transistor. Before characterizing the transistor properties of the self-aligned devices, gate leakage current (I_{gs}) from the gate stack to the underlying graphene is measured from −4 V to 4 V gate voltage, which indicates the gate leakage current is negligible during the measurement. FIG. 28B shows the I_{ds}−V_{ds} output characteristic of a 300 nm channel length self-aligned graphene transistor at various gate voltages. The maximum scaled on-current of 1.73 mAμm⁻¹ can be achieved at V_{ds}=−1 V with slight current saturation. The current saturation is desirable for the power gain performance in radio frequency (RF) graphene transistors.

The I_{ds}−V_{TG} curve of the same device is measured at different drain bias from 100 mV to 600 mV as the top gate voltage sweeps from 0 V to 3 V (FIG. 28C). It shows a typical characteristic of p-type doping with the Dirac points located at positive top gate voltage, which can be attributed to oxygen doping during the growth or transfer process. Overall, the hole transport branch can switch from saturation current to Dirac point within 2 V top gate voltage, indicating strong top gate coupling. In general, these top-gated, self-aligned graphene transistors exhibit a very small I_{ds}−V_{TG} hysteresis of ˜0.1 V or less, demonstrating the relatively clean nature of the graphene-dielectric interface. A suppression of electron transport branch is observed in the I_{ds}−V_{TG} transfer curves. This electron-hole asymmetry may be originated from the misalignment between the work function of contact electrode and the neutrality point of the channel. A trend of negative shift of Dirac point is observed with increasing drain voltage, potentially arising from a shift in the Dirac point by 1/2 ΔV_{ds} with a change of bias voltage ΔV_{ds} due to the relative potential between the gate and drain.

In order to characterize the gate capacitance, the conductance of one graphene transistor with 300 nm channel length and 22 nm dielectric thickness is measured as a function of both top gate (V_{TG}) and back gate (V_{BG}) voltage (FIG. 28D). The ratio between the top gate and back gate capacitance is extracted from slope of the linear shift trajectory of the Dirac point as a function of both the top gate and back gate voltage, which gives a value for C_{TG}/C_{BG} of about 29. For 300 nm SiO₂, the back-gate capacitance is C_{BG}=11.5 nF cm⁻², and, therefore, the estimated top gate capacitance is C_{TG}=334 nF cm⁻², which is consistent with the result obtained from geometry based finite-element calculations (C_{TG}=359 nF cm⁻²).

FIG. 28E shows the I_{ds}−V_{TG} transfer curves of several devices with variable self-aligned gate lengths ranging from 3 μm to 100 nm. With decreasing channel length, a general trend of positive shift of Dirac point and decrease of on/off ratio is observed, which can be explained by short channel effect: in a short channel device, the off-state energy barrier is strongly affected by drain voltage, thereby increasing the off-state current and involving higher gate voltage to turn off the channel. FIG. 28F shows the extracted transconductance, gₘ=|dI_{ds}/dV_{TG}|, for devices with different channel lengths. The peak transconductance at bias of 600 mV increases from 0.11 mS/μm (L=3 μm) to 0.53 mS/μm (L=300 nm). But a further shrinkage of channel length to 100 nm leads to a reduction of transconductance to 0.45 mS/μm. This reduction may be explained by the possibility that the decreasing of channel length can result in increased Klein tunneling and thereby less effective gate modulation.

The above discussion demonstrates that the self-aligned graphene transistors with transferred gate stacks exhibit excellent DC performance. To further determine the cut-off frequency (f_{T}) of the devices, on-chip microwave measurements were carried out with an Agilent 8361A network analyzer in the range of 50 MHz˜30 GHz. The graphene transistors for rf measurement are fabricated on glass substrate in order to reduce the parasitic capacitance. To accurately assess the intrinsic f_{T} value, de-embedding procedures are performed using the exact pad layout as “open,” “short,” and “through” structures on the same chip. The de-embedded S parameters constitute a set of coefficients to describe intrinsic input and output behavior of graphene transistors.

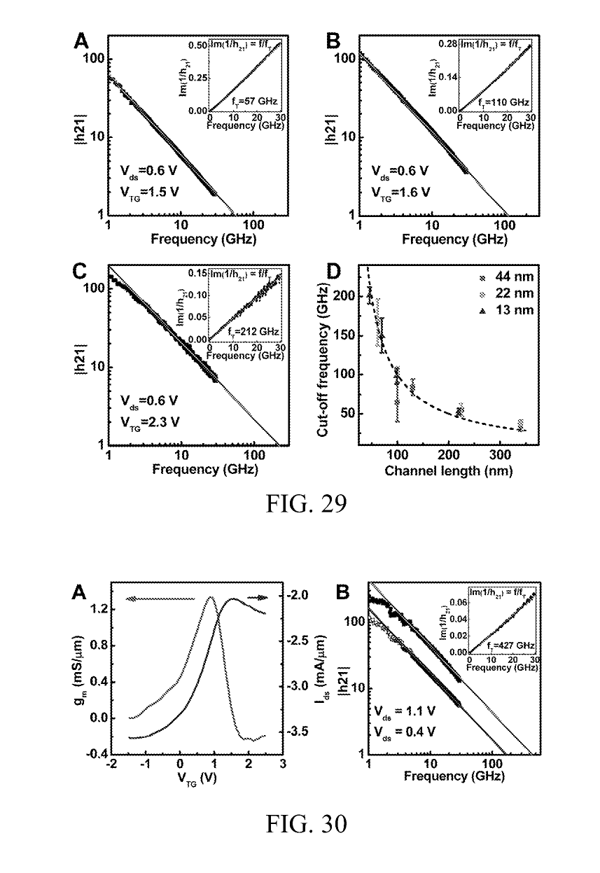

FIG. 29A shows the small signal current gain |h21| extracted from the measured S parameters at V_{TG}=1.5 V and V_{ds}=0.6 V in a 220 nm channel length graphene transistor. The curve shows a typical 1/f frequency dependence expected for an ideal field effect transistor (FET). The linear fit yields a f_{T} value of 57 GHz for this particular device (FIG. 29A), which is also verified using Gummel's approach (FIG. 29A, inset). To further probe the limit of the frequency response, we have fabricated graphene transistors with smaller channel lengths. FIG. 29B, C show the result extracted from another two self-aligned graphene transistors with 100 nm and 46 nm channel length. The cut-off frequency is f_{T}=110 GHz and f_{T}=212 GHz, respectively. After the RF measurement, the S parameters were analyzed for all three devices. The device component values (including gate-source capacitance, gate-drain capacitance, and transconductance) derived from the RF measurements are consistent with those obtained from the DC measurements and finite element simulations, demonstrating the validity of the RF measurements and the de-embedding procedures.

To further investigate the reproducibility of the approach and examine the length-scaling relations, more than 40 graphene transistors of variable channel lengths (L) and dielectrics thicknesses were examined. In general, the peak cut-off frequencies follow a 1/L dependence. Although 1/L² dependence was observed in longer channel devices, the contact resistance dominating the total resistance and transconductance degradation in short channel transistors leads to the 1/L dependence of the cut-off frequency. For devices with dielectric thickness of 44 nm, the cut-off frequency falls beneath the 1/L trend when the channel length shrinks to 100 nm. This phenomenon can be attributed to the short channel effect, in which the gate modulation is less effective when the channel length is reduced. The RF performance of the device can be further improved by minimizing the contact resistance or decreasing the gate dielectrics thickness to improve gate coupling.

The cut-off frequency of the self-aligned devices shows a significant improvement over previously reported CVD graphene transistors of comparable channel length (e.g., f_{T}˜212 GHz for 46 nm device in the current approach vs. 155 GHz for 40 nm device). Nonetheless, the performance of these devices is below those obtained from peeled graphene, which suggests that the performance of the devices may be affected by the quality of CVD graphene rather than the fabrication process. To demonstrate that the current approach is applicable for higher performance devices, studies were carried out for the self-aligned transistors on peeled graphene. The devices are fabricated on highly resistive Si substrate with 300 nm SiO₂ due to the difficulty of visualizing the peeled graphene on glass substrate. To accurately assess the intrinsic f_{T} value, de-embedding procedures are performed using the substantially identical pad layout as “open,” “short,” and “through” structures on the same chip. Of note, electrical characterization shows graphene transistors with substantially higher intrinsic cut-off frequency can be obtained in this way. The I_{ds}−V_{TG} transfer of a 67 nm device shows a maximum scaled on-current of 3.56 mA/μm and a peak scaled transconductance of about 1.33 mS/μm is obtained at V_{ds}=1 V (FIG. 30A). FIG. 30B shows the small signal current gain |h21| of a 67 nm channel length graphene transistor with a typical 1/f frequency dependence and an extracted f_{T} value of about 427 GHz at V_{ds}=1.1 V (FIG. 30B and inset). Additionally, a f_{T} value of about 169 GHz can be obtained at V_{ds}=0.4 V, indicating a linear trend of f_{T} value with source-drain voltage.

In summary, this example demonstrates a scalable method to fabricate self-aligned graphene transistors on glass with transferred gate stacks. With a substantially damage-free transfer process and self-aligned device structure, the fabricated graphene transistors exhibit higher cut-off frequencies in both CVD grown graphene transistors (about 212 GHz) and peeled graphene transistors (about 427 GHz) that other reported graphene transistors. This study opens a pathway to scalable fabrication of high speed self-aligned graphene transistor arrays on arbitrary substrates.

Fabrication of Self-Aligned Graphene Transistors with Transferred Gate Stacks:

First, a gold thin film (about 50 nm) is deposited on a Si/SiO₂ substrate using e-beam evaporation. An Al₂O₃ top gate dielectric film is then deposited on the gold surface by ALD at about 250° C. The Al₂O₃ top gate dielectric film is then patterned by anisotropic reactive-ion etching (RIE) etching using e-beam patterned metal strips as the etching mask to form metal-dielectrics stack structure. Then the Al₂O₃ sidewall is formed by using ALD at about 250° C. The anisotropic RIE etching is employed to etch away the dielectric on top of the gold, leaving the rest covered by the side wall of the gate dielectric stack. A thin layer of AZ4620 photoresist (˜xx μm) is then spin coated onto the substrate to wrap around the gate stack. A thermal release tape (TRT) is attached onto the top of the substrate. Then the whole structure is immersed in deionized (DI) water at room temperature, followed by the peeling-off an edge of the TRT. The gold layer is then etched away using gold etchant. Then the TRT and the attached top gate structure is then laminated onto patterned graphene strips. A peeling off process is operated at the glass transition point of the photoresist, followed by repeated acetone rinse in order to remove the photoresist. E-beam lithography and vacuum metallization (Ti/Au, about 50 nm/50 nm) are used to define the source, drain, and gate electrodes. A thin layer of Pd/Au metal (about 5 nm/10 nm) is then deposited across the gate stack to form the self-aligned source and drain electrodes. The microstructures and morphologies of the nanostructures are characterized by a JEOL 6700 SEM. The cross-section image of the self-aligned device is obtained by an FEI Titan TEM.

Device Measurement:

The DC electrical transport measurements are conducted with a Lakeshore probe station (Model CRX-4K) and a computer-controlled analog-to-digital converter (National Instruments model 6030E) under ambient conditions. The on-chip microwave measurements are carried out in the range of 50 MHz to 30 GHz using Cascade RF probes and an Agilent 8361A network analyzer under ambient conditions. The measured S-parameters are de-embedded using specific “short” and “open” structures with substantially identical layout to remove the parasitic capacitance and resistance associated with the pads and connections. The “through” calibration is carried out with exact layout with gate shorted to drain, and the “load” calibration is carried out with a standard calibration pad.

For “open” structures, the gate stacks are transferred onto a desired substrate, followed by e-beam lithography and metallization (Ti/Au, about 70 nm/50 nm) process to define the source, drain, and gate electrodes. A thin layer of Pd/Au metal with substantially the same area as that of the actual device is then deposited across the gate stack, in which the gate stack separates the Pd/Au thin film into two isolated regions that form the self-aligned source and drain electrodes precisely close to the gate stack. For “short” structures, the stacks are transferred onto a desired substrate, followed by the formation of gate and self-aligned source and drain electrodes. Then the gate stacks and the self-aligned electrodes are shorted by a narrow strip of Ti/Au film. For “through” structures, the substantially identical ground-signal-ground layout is fabricated with the gate electrodes directly shorted to drain electrodes with a 10 μm wide Ti/Au lead.

Synthesis and Transfer Process of CVD Grown Graphene:

The graphene is grown by chemical vapor deposition on copper foil at about 1050° C. with methane as the carbon-containing precursor. At first, Cu foils (about 25 μm thick, 99.8%, Alfa Aesar) are loaded into a 1 inch quartz tube inside a horizontal furnace of a CVD system. The furnace is then allowed to heat up to about 1080° C. with H₂/Ar flow (25 sccm/475 sccm) to anneal the Cu foil for about 90 minutes. After annealing, the temperature is dropped to about 1050° C. in about 10 minutes. The graphene growth is initiated by feeding methane (500 ppm methane in Ar, 35 sccm) balanced with the H₂/Ar (25 sccm/440 sccm). After growth, the graphene is transferred onto SiO₂/Si substrate or another substrate for characterization and device fabrication. Initially, the graphene is grown on both sides of the copper foils. To transfer the graphene, a layer of PMMA film is spin coated onto one side of the graphene/Cu foil, and the other side is cleaned with O₂ plasma. The copper is then etched away using copper etchant by floating the foil on the surface of the etchant bath. The PMMA/graphene film is washed with HCl/H₂O (1:10) and DI water for several times, and transferred onto a desired substrate.

Raman Spectroscopy of the CVD Grown Graphene on SiO₂:

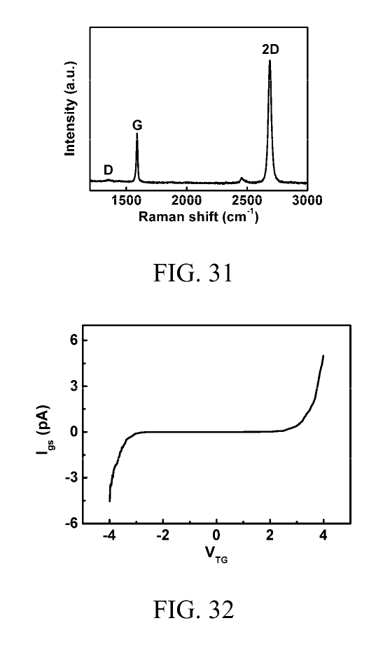

FIG. 31 shows the Raman spectrum of CVD grown graphene on a SiO₂/Si substrate. The ratio of G peak to 2D peak reveals the single layer property of CVD grown graphene.

Gate-Leakage Current of the Self-Aligned Graphene Device:

FIG. 32 shows gate-leakage current vs. top gate voltage (I_{gs}−V_{TG}). With the self-aligned Pd/Au source drain electrodes, the gate-source leakage remains very small compared to the channel current in the range of V_{TG}=−4 V to 4 V. The leakage current does not significantly affect the transistor characteristics.

The Hysteresis of I_{DS}−V_{TG} Curve:

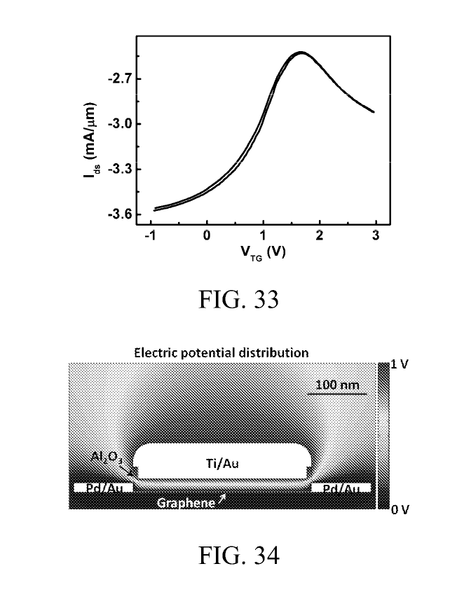

FIG. 33 shows the back and forth sweep of I_{ds}−V_{TG} curve of a peeled graphene device with transferred gate stack. The curve shows a small hysteresis <0.07 V under ambient conditions at V_{ds}=−1 V, highlighting the excellent dielectric quality of the gate stack.

Finite Element Simulation of Electrostatic Capacitance Between the Gate Stack and Graphene:

FIG. 34 shows finite element simulation of the electrostatic capacitance between a transferred gate stack and graphene. The simulated electrostatic capacitance normalized by graphene channel area is about 359 nF/cm².

The Component Parameter Values for Three CVD Grown Graphene Devices:

Table 4 sets forth the component parameter values for three CVD grown graphene devices. f_{T} is the cut-off frequency with de-embedding. The projected f_{T} values for all devices with de-embedding process can be determined based on DC device parameters. Also, various device parameters (including C_{gs}, C_{gd}, gₘ, and f_{T}) derived from S-parameters are consistent with the values determined from DC measurements or electrostatic simulations, demonstrating the validity of the RF measurements and the de-embedding procedures.

TABLE 4

| | Width | Length | gₘ | C_{gs} | C_{gd} | Projected f_{T} | f_{T} |
|---|---|---|---|---|---|---|---|
| Device | (μm) | (nm) | (mS) | (fF) | (fF) | (GHz) | (GHz) |
| 1 | 8 | 220 | 3.9 | 8.10 | 2.86 | 56 | 57 |
| 2 | 8 | 100 | 3.5 | 3.86 | 1.03 | 114 | 110 |
| 3 | 8 | 46 | 3.4 | 2.04 | 0.41 | 221 | 212 |

### Example 8

Preparation of Graphene Substrate:

Graphene is grown on a copper foil by chemical vapor deposition. Both sides of the copper foil are substantially covered with a single layer of graphene. About 200 nm of poly(methyl methacrylate) (PMMA) is spin-coated onto the copper/graphene foil and baked at about 130° C. for about 2 mins. The back side (without polymer coating) is treated with oxygen plasma to etch away the back side graphene (about 70 W for about 50 seconds). This copper/graphene/PMMA substrate is floated onto 0.1 g/mL iron chloride solution with the polymer side face up to etch away the copper foil, leaving the graphene/PMMA film floating in the solution. The polymer film is carried by a silicon wafer and transferred to a clean deionized water bath. At this time, the polymer film is floated on the deionized water with PMMA faced up so that salt ions absorbed on the graphene side will diffuse away. This process is repeated for 3 times to ensure thorough cleaning of the graphene. After the cleaning process, the graphene/PMMA film is lifted onto a desired substrate, such as Si/SiO₂, Si/SiNₓ, or a flexible substrate such as polyimide or polydimethylsiloxane (PDMS), with graphene side faced to the substrate. This substrate is dried under vacuum for about 2 hrs at room temperature. The PMMA layer is removed using acetone solution or hot acetone vapor.

Alternative graphene substrate includes mechanically peeled graphene onto a substrate such as Si/SiO₂ or Si/Al₂O₃ substrate, epitaxial grown graphene on a SiC substrate, substrate with graphene prepared in solution, and so forth.

Transfer of Dielectric onto Graphene Substrate:

A dielectric layer is grown on a flat substrate with sacrificial layer on top. Typical substrate used here is a polished silicon wafer, and the sacrificial layer is an e-beam evaporated metal film (e.g., Ni or Au with about 150 nm to about 500 nm in thickness). High-k dielectric material HfO₂ is grown on top of the sacrificial layer using ALD at about 250° C. Then, the dielectric thin film is patterned into strips according to a final device dimension by e-beam lithography or photolithography. After that, the patterned dielectric substrate is spin-coated with about 200 nm to about 400 nm PMMA thin film and annealed at about 130° C. for about 5 mins. The sacrificial layer is etched away by a metal etchant so that a polymer thin film embedded with HfO₂ dielectric strips can be obtained. This film is washed with deionized water and lifted out by the graphene substrate mentioned above. After drying under vacuum for about 2 hrs, the PMMA is removed by acetone liquid or hot acetone vapor, leaving HfO₂ dielectric on top of the graphene substrate. The resulting substrate is annealed under high vacuum (about 10⁻⁵ torr or more) at about 100° C. to about 200° C. for a couple of hours to remove trapped water molecules between graphene and the dielectric layer.

Alternative Transfer Methods:

Thermal tape can be used to replace the PMMA film to transfer the dielectric strips on the graphene substrate. The thermal tape adheres to the patterned dielectric substrate by firmly pressing them together. The dielectric strips are peeled off with the thermal tape after dissolving the metal sacrificial layer with a metal etchant. Then, the dielectric/thermal tape is firmly pressed onto the graphene substrate, and the thermal tape is released when heated at about 100° C., leaving patterned dielectric strips on top of the graphene substrate. When using a thermal tape as the transfer media, spin-coated PMMA thin film can be also used as a sacrificial layer, using acetone as an etchant to peel off the dielectric strips. This sacrificial PMMA film is prepared by spin coating PMMA film (about 200 nm to about 400 nm) on top of a flat substrate, such as a polished Si wafer, and cured at about 130° C.

Another method involves directly integrating the graphene/dielectric. First, the dielectric is grown on top of a sacrificial layer (e.g., HfO₂ on top of Ni, Au, or PMMA; Al₂O₃ on top of Au or PMMA) and patterned according to a device dimension by e-beam lithography or photolithography. Then chemical vapor deposition grown graphene is transferred onto the dielectric substrate. Annealing away remaining water, this substrate is coated with SU8 resist (about 5 μm in thickness) and further adhered to a targeted hard substrate (e.g., Si) or a flexible substrate (e.g., polyimide). After hardening the SU8 at about 150° C., the dielectric/graphene/SU8 substrate is peeled off from the original substrate by dissolving away the sacrificial layer. A pre-prepared PDMS film can be directly stamped onto the sacrificial layer/dielectric/graphene substrate. After dissolving the sacrificial layer, the dielectric/graphene layer is adhered to the PDMS substrate. This flexible substrate can be directly used for device fabrication.

Another transfer method is to integrate the graphene/dielectric based on transferring fabricated graphene transistor from a sacrificial substrate. The top gate metal electrode (Au/Ti) is firstly patterned on top of a sacrificial layer using e-beam lithography or photolithography before deposition of a high-k dielectric. After ALD growth of the dielectric layer, chemical vapor deposition grown graphene is transferred onto the dielectric surface, and the source-drain electrodes are pattered according to a position of the pre-patterned gate electrode. The device is transferred to another insulating substrate using SU8 as the adhesion layer or using PDMS stamping method as described above.

### Example 9

Bilayer Graphene for Terahertz Transistors:

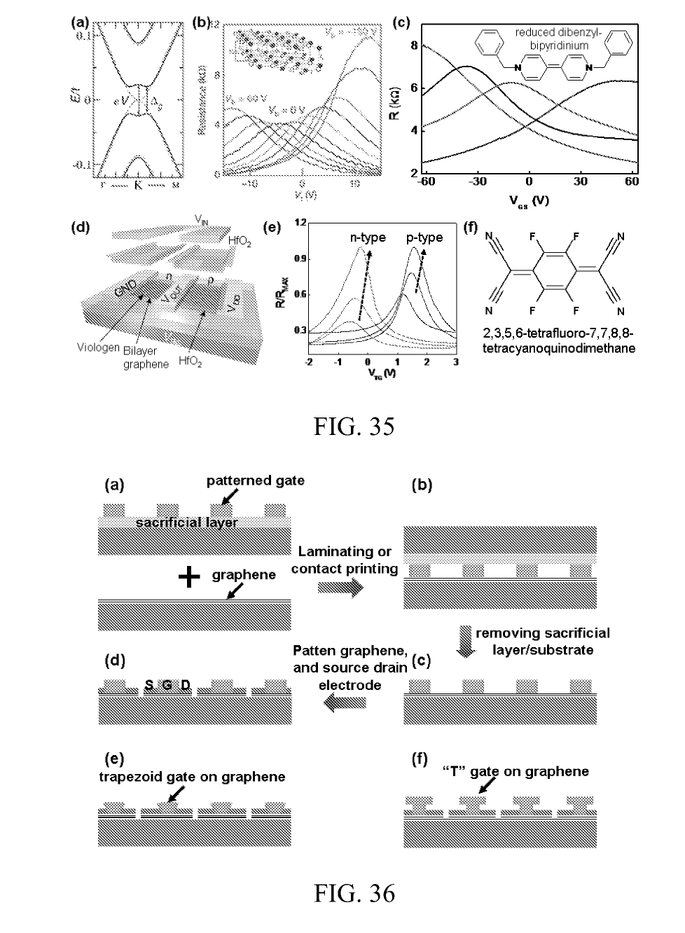

Bilayer graphene is of interest because of the feasibility to tune its band gap with a vertical displacement field to break the inversion symmetry. Studies have suggested that a bandgap can be opened in the Bernal-stacking (AB-stacking) bilayer graphene by applying an external electric filed normal to the graphene plane (FIG. 35a). This suggestion has been experimentally verified by optical measurements and electrical measurements (FIG. 35b). It is particularly interesting to note that the transconductance (gₘ) and on/off ratio of bilayer graphene devices increase significantly upon the application of the vertical displacement field, which opens another pathway to improve the cut-off frequency (f_{T}) of the graphene transistors since the cut-off frequency is typically proportional to transconductance according to relation f_{T}=gₘ/(2πC_{G}). However, the improved transconductance in such bilayer graphene devices is typically achieved with very high voltages applied to both the top and bottom gates due to the large vertical displacement field. Furthermore, with both a top- and a bottom-gate, this device geometry can introduce substantial parasitic capacitance that impedes frequency response.

To this end, an approach is developed to use chemical molecular doping to reduce or even completely replace the vertical displacement gate voltage. In this case, the application of chemical molecular doping in bilayer graphene can create an effective offset voltage to not only give rise to additional displacement field for bandgap opening, but also shift the Fermi energy level for tunable Dirac points. Of note, by applying electron rich molecules (with high HOMO (highest occupied molecular orbital) level) on the surface of a bilayer graphene, it is possible to progressively dope the top-layer graphene with electrons and tune the bandgap and therefore the transconductance and on-off ratio with a single back gate (FIG. 35c). With this approach, it is demonstrated that the on-off ratio, transconductance and Dirac point of bilayer graphene devices can be readily tuned (FIG. 35d,e) by applying different amount of molecules. Using a similar strategy, by selectively doping the bottom layer graphene of a bilayer graphene, it should allow the tuning of the bandgap and transconductance of bilayer graphene device with a single top gate. Additionally, by using molecules of different HOMO and LUMO (lowest unoccupied molecular orbital) levels to selectively dope the top- and bottom layer with either electrons or holes can allow further flexibility to tune the bandgap or Diract point of the device without double gates. This strategy thus opens the possibility to apply bilayer graphene for high speed transistors without a second gate that can cause large parasitic capacitance. Within this proposal, either electron rich (e.g., reduced dibenzyl-bipyridinium, FIG. 35c) or deficient (e.g., tetrafluoro-tetracyanoquinodimethane, FIG. 35f) molecules can be used to dope the top or bottom-layer of graphene to increase the band gap and transconductance of bilayer graphene devices with self-aligned gate. With this strategy, the transconductance can be increased for further improved cut-off frequency in bilayer graphene devices (according to f_{T}=gₘ/(2πC_{G})).

Integrated High Speed Graphene Transistor Arrays:

For practical applications, it is desirable to demonstrate the scalability of the approach for the fabrication of large array of high speed graphene transistors. To this end, a chemical vapor deposition (CVD) approach is used to grow large area graphene on copper foil and then transferred the graphene onto glass or plastic substrates, which will be used as the base material for the fabrication of large array of graphene transistors. The graphene will be patterned, and an array of nanowire gates will be aligned onto the graphene using a dielectrophoresis assembly process to obtain a large array of graphene transistors (FIG. 36). Of note, single nanowires can be assembled over large areas in high yield with a precise control of their spatial location (FIG. 36 inset), demonstrating the feasibility of this approach for the scalable fabrication of RF graphene circuits.

Alternatively, the nanowire gate array can also be defined on a first substrate using a nanolithography approach (e.g., conventional e-beam, photolithography or imprint nanolithography), and then transferred onto a large sheet of CVD graphene on glass or plastic substrates through a contact-printing transfer (soft lithography) approach, to create large arrays of graphene transistors (FIG. 36). In this case, a sub-100 nm wide gate array is first fabricated on a flat substrate with a sacrificial layer. High-k dielectric material such as HfO₂ is then grown on top. The gate array is then transferred onto CVD graphene through a contact printing approach. The sacrificial layer is then removed to release the gate array onto the graphene for subsequent device fabrication using the approach described above. Of note, with this soft-lithography based approach, the shape of the gate (e.g. m “inverted triangle”, “trapezoid”, or ‘T’ gate) can be precisely designed and fabricated to simultaneously keep a short gate length and a small gate resistance (FIG. 36e,f).

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, operation or operations, to the objective, spirit and scope of the invention. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations is not a limitation of the invention.

What is claimed is:

1. A graphene transistor, comprising:
a substrate;
a source electrode disposed on the substrate;
a drain electrode disposed on the substrate;
a graphene channel disposed on the substrate and extending between the source electrode and the drain electrode; and
a top gate disposed on the graphene channel and including a nanostructure.

2. The graphene transistor of claim 1, wherein the nanostructure is disposed on the graphene channel and includes a dielectric.

3. The graphene transistor of claim 2, wherein the dielectric has a dielectric constant of at least 9.

4. The graphene transistor of claim 2, wherein the nanostructure corresponds to a dielectric nanowire.

5. The graphene transistor of claim 2, wherein the nanostructure corresponds to a dielectric nanoribbon.

6. The graphene transistor of claim 2, wherein the nanostructure corresponds to a nanowire including an electrically conductive core and a dielectric shell partially surrounding the electrically conductive core, and the dielectric shell is disposed on the graphene channel.

7. The graphene transistor of claim 1, wherein the nanostructure is disposed on the graphene channel and includes a doped semiconductor that forms a potential barrier at an interface with the graphene channel.

8. The graphene transistor of claim 1, wherein the nanostructure extends transversely relative to the graphene channel.

9. The graphene transistor of claim 8, wherein the source electrode includes a first main block portion and a first extension portion that extends between the first main block portion and the nanostructure, and the drain electrode includes a second main block portion and a second extension portion that extends between the second main block portion and the nanostructure.

10. The graphene transistor of claim 9, wherein a length of the graphene channel corresponds to a width of the nanostructure.

11. The graphene transistor of claim 9, wherein the nanostructure functions as a physical shadow mask to define a placement of the first extension portion and the second extension portion relative to the nanostructure.

12. The graphene transistor of claim 10, wherein the length of the graphene channel is in the nm range.

13. The graphene transistor of claim 11, wherein the length of the graphene channel is in the middle nm range.

14. The graphene transistor of claim 1, wherein the graphene transistor has an on-current of at least 1.2 mA μm⁻¹, as scaled by a width of the graphene channel and as measured at a drain-source voltage of 1 V and a top gate voltage of −1 V.

15. The graphene transistor of claim 1, wherein the nanostructure corresponds to one of a HfO₂ nanowire, an Al₂O₃ nanoribbon, a nanoribbon including at least one layer of BN, a nanoribbon including a layer of Al₂O₃ and a layer of HfO₂.

16. The graphene transistor of claim 1, wherein the substrate corresponds to one of a glass substrate, a silicon substrate including a layer of silicon oxide, and a polymer substrate.

17. A graphene transistor, comprising:
a source electrode;
a drain electrode;
a graphene channel extending between the source electrode and the drain electrode; and
a gate stack including:
a dielectric layer disposed on the graphene channel;
an electrically conductive layer disposed on the dielectric layer, and
a dielectric spacer at least partially covering sidewalls of the electrically conductive layer.

18. The graphene transistor of claim 17, wherein the gate stack is formed separately, and is transferred onto the graphene channel.

19. The graphene transistor of claim 17, wherein the source electrode includes a first main block portion and a first extension portion that extends between the first main block portion and the gate stack.

20. The graphene transistor of claim 19, wherein the drain electrode includes a second main block portion and a second extension portion that extends between the second main block portion and the gate stack.

21. The graphene transistor of claim 20, wherein the gate stack extends transversely relative to the graphene channel.

22. The graphene transistor of claim 21, wherein a length of the graphene channel corresponds to a width of the gate stack.

23. The graphene transistor of claim 17, wherein the graphene transistor has a transconductance of at least 1 mS μm⁻¹, as scaled by a width of the graphene channel and as measured at a drain-source voltage of 1 V.

24. The graphene transistor of claim 17, wherein the graphene transistor has a carrier mobility of at least about 1000 cm²V⁻¹s⁻¹.

25. The graphene transistor of claim 17, wherein the graphene channel includes a bilayer of graphene.
